(19) United States
(12) Patent Application Publication
(10) Pub. No.: US 2024/0212884 A1
(43) Pub. Date: Jun. 27, 2024

(54) LIGHTWEIGHT CRYOGENIC CONDUCTORS AND METHODS OF MAKING AND USE THEREOF

(71) Applicant: GEORGIA TECH RESEARCH CORPORATION, Atlanta, GA (US)

(72) Inventors: Lukas GRABER, Atlanta, GA (US); Alfonso J. CRUZ, Atlanta, GA (US); Zhiyang JIN, Atlanta, GA (US); Chunmeng XU, Atlanta, GA (US); Amrita GHOSH, Atlanta, GA (US)

(21) Appl. No.: 18/557,693

(22) PCT Filed: Apr. 29, 2022
(86) PCT No.: PCT/US2022/027064

§ 371 Date: Oct. 27, 2023

Related U.S. Application Data
(60) Provisional application No. 63/181,675, filed on Apr. 29, 2021.

(51) Int. Cl. H01B 12/04; H01B 13/00; H10N 69/00

(52) U.S. Cl. CPC H01B 12/04; H01B 13/0036; H10N 69/00

(57) ABSTRACT

Disclosed herein are cryogenic wires and methods of making and use thereof. For example, disclosed herein are cryogenic wires comprising a conductor having a mass density of 5000 kg/m³ or less; and a cladding material disposed around the conductor, the cladding material comprising a ductile and malleable metal, wherein the conductor comprises lithium, beryllium, calcium, sodium, magnesium, titanium, or a combination thereof. In some examples, the conductor comprises lithium or an alloy thereof, beryllium or an alloy thereof, calcium or an alloy thereof, sodium or an alloy thereof, magnesium or an alloy thereof, titanium or an alloy thereof, or a combination thereof.

### CROSS-REFERENCE TO RELATED APPLICATIONS

This application claims the benefit of priority to U.S. Patent Application No. 63/181,675 filed Apr. 29, 2021, which is hereby incorporated herein by reference in its entirety.

### BACKGROUND

Cryogenic wires have a higher thermal conductivity and higher electrical conductivity, than other conventional conductors (such as copper wires). Lightweight conductors with suitability ductility are needed for electrical power applications where the gravimetric power density matters. The compositions and methods disclosed herein address these and other needs.

### SUMMARY

In accordance with the purposes of the disclosed materials and methods, as embodied and broadly described herein, the disclosed subject matter relates to cryogenic wires and methods of making thereof.

In some examples, provided herein is a cryogenic wire extending from a first end to a second end opposite and axially spaced apart from the first end, the cryogenic wire comprising a conductor having a mass density of 5000 kg/m³ or less; and a cladding material disposed around the conductor, the cladding material comprising a ductile and malleable metal.

In some examples, the conductor comprises lithium, beryllium, calcium, sodium, magnesium, titanium, or a combination thereof. In some examples, the conductor comprises lithium or an alloy thereof, beryllium or an alloy thereof, calcium or an alloy thereof, sodium or an alloy thereof, magnesium or an alloy thereof, titanium or an alloy thereof, or a combination thereof.

In some examples, the cladding materials comprises aluminum, copper, silver, or a combination thereof. In some examples, the cladding material comprises copper. In some examples, wherein the cladding material comprises silver.

In some examples, the conductor has an electrical conductivity per unit density of from 500 to 22,000 S·m²/kg or from 6,500 to 21,000 S·m²/kg at room temperature. In some examples, the conductor has an electrical conductivity per unit density of from 2,500 to 410,000 S·m²/kg or from 32,000 to 410,000 S·m²/kg at 100 K. In some examples, the conductor has an electrical conductivity per unit density of from 4,500 to 750,000 S·m²/kg or from 58,000 to 750,000 S·m²/kg at 77 K. In some examples, the conductor has an electrical conductivity per unit density of from 950,000 to 16,000,000 S·m²/kg or from 1,100,000 to 16,000,000 S·m²/kg at 20 K.

In some examples, the cryogenic wire has an electrical resistivity of from 1.6×10⁻⁷ to 4.5×10⁻⁷ Ω·m or from 3.2×10⁻⁷ to 1.7×10⁻⁷ Ω·m at room temperature. In some examples, the cryogenic wire has an electrical resistivity of from 1.0×10⁻⁹ to 8.0×10⁻⁸ Ω·m or from 1.0×10⁻⁹ to 3.4×10⁻⁹ Ω·m at 100 K. In some examples, the cryogenic wire has an electrical resistivity of from 7.3×10⁻¹⁰ to 4.7×10⁻⁷ Ω·m or 7.3×10⁻¹⁰ to 1.9×10⁻⁹ Ω·m at 77 K. In some examples, the cryogenic wire has an electrical resistivity from 1.0×10⁻¹² to 1.5×10⁻⁹ Ω·m, from 1.0×10⁻¹⁰ to 1.5×10⁻⁹ Ω·m, or from 7.0×10⁻¹² to 1.5×10⁻¹¹ Ω·m at 20 K.

In some examples, the cryogenic wire has a thermal conductivity of from 15 to 250 W/(m·K) at room temperature. In some examples, the cryogenic wire has a thermal conductivity of from 25 to 1500 W/(m·K) at 90 K. In some examples, the cryogenic wire has a thermal conductivity of from 25 to 2500 W/(m·K) at 70 K. In some examples, the cryogenic wire has a thermal conductivity of from 25 to 12,000 W/(m·K) or from 25 to 4000 W/(m·K) at 20 K.

In some examples, the cryogenic wire has an average diameter of from 0.05 millimeters (mm) to 12.0 mm.

In some examples, the first end of the cryogenic wire is covered, thereby preventing the conductor from contacting atmospheric air at the first end. In some examples, the first end is capped.

In some examples, the second end of the cryogenic wire is covered, thereby preventing the conductor from contacting atmospheric air at the second end. In some examples, the second end is capped.

In some examples, the cryogenic wire further comprises a varnish, wherein the varnish is disposed on the cladding material, such that the cladding material is between the varnish and the conductor. In some examples, the varnish is insulating. In some examples, the varnish comprises enamel.

Also provided herein is a multifilamentary cable comprising two or more cryogenic wires, each of the two or more cryogenic wires independently being the cryogenic wire as described herein, wherein the two or more cryogenic wires are bound together.

Further provided herein is a method of making a cryogenic wire as described herein, the method comprising at least partially filling a lumen of a conduit with the conductor, wherein the conduit comprises a wall defining the lumen, wherein the wall comprises the cladding material, and wherein the conductor is a solid.

In some examples, the conductor is a solid rod.

In some examples, the conductor is a powder.

In some examples, the method further comprises heating the cryogenic wire until the conductor is molten and/or to anneal the cladding material.

In some examples, the cryogenic wire is heated to a temperature 5 K or less above the melting point of the conductor.

In some examples, the cryogenic wire has a cross-sectional area and a length, and wherein the method further comprises drawing the cryogenic wire to decrease the cross-sectional area and increase the length of the cryogenic wire.

In some examples, the cryogenic wire is drawn through series of dies each having an incrementally smaller cross-sectional area with a set of calendar rollers.

In some examples, the method further comprises cooling the cryogenic wire to room temperature before drawing the cryogenic wire.

Also provided herein is a method of making a cryogenic wire, the cryogenic wire extending from a first end to a second end opposite and axially spaced apart from the first end, the method comprising at least partially filling a lumen of a conduit with a conductor, wherein the conductor is molten, thereby being a molten conductor, wherein the conduit extends from a third end to a fourth end opposite and axially spaced apart from the third end, wherein the conduit comprises a wall defining the lumen, wherein the wall comprises a cladding material, wherein the cladding material comprises a ductile and malleable metal, thereby forming the cryogenic wire comprising the cladding material disposed around the conductor.

In some examples, at least partially filling the conduit with the conductor comprises submerging the first end of the conduit in the molten conductor; and applying a negative pressure to the second end of the conduit to thereby pull the molten conductor into the lumen of the conduit.

In some examples, the negative pressure is applied by a vacuum pump, the vacuum pump being in fluid communication with the lumen of the conduit.

In some examples, the negative pressure is applied by pulling a plunger on a syringe, wherein the syringe is in fluid communication with the lumen of the conduit.

In some examples, the syringe is coupled to a second conduit, the second conduit is coupled to the second end of the conduit, and the second conduit is in fluid communication with the syringe and the lumen of the conduit.

In some examples, the second conduit is a plastic heat-resistant hose.

In some examples, at least partially filling the conduit with the conductor occurs in an inert atmosphere having an oxygen concentration of 2% or less by volume. In some examples, the inert atmosphere comprises nitrogen, argon, or a combination thereof. In some examples, the inert atmosphere comprises nitrogen. In some examples, the inert atmosphere comprises argon.

In some examples, the method further comprises heating a solid conductor until molten, thereby forming the molten conductor, wherein the solid conductor has a density of 5000 kg/m³ or less. In some examples, the solid conductor is a solid rod. In some examples, the solid conductor is a powder.

In some examples, the method further comprises cooling the molten conductor to solidify the molten conductor, such that the cryogenic wire comprises the cladding material disposed around a solid conductor.

In some examples, the cryogenic wire has a cross-sectional area and a length, and wherein the method further comprises drawing the cryogenic wire to decrease the cross-sectional area and increase the length of the cryogenic wire. In some examples, drawing the cryogenic wire comprises drawing the cryogenic wire through a series of dies each having an incrementally smaller cross-sectional area. In some examples, the cryogenic wire is drawn through the series of dies with a set of calendar rollers.

In some examples, the method further comprises submerging the cryogenic wire in mineral oil before drawing.

In some examples, the method further comprises spooling the cryogenic wire.

In some examples, the method further comprises applying a varnish to coat the cryogenic wire. In some examples, the varnish is insulating. In some examples, the varnish comprises enamel.

In some examples, the method further comprises covering the first end of the cryogenic wire, thereby preventing the conductor from contacting atmospheric air at the first end. In some examples, covering the first end comprises capping the first end.

In some examples, the method further comprises covering the second end of the cryogenic wire, thereby preventing the conductor from contacting atmospheric air at the second end. In some examples, covering the second end comprises capping the second end.

In some examples, the conductor comprises lithium, beryllium, calcium, sodium, magnesium, titanium, or a combination thereof. In some examples, the conductor comprises lithium or an alloy thereof, beryllium or an alloy thereof, calcium or an alloy thereof, sodium or an alloy thereof, magnesium or an alloy thereof, titanium or an alloy thereof, or a combination thereof.

In some examples, the cladding material comprises copper, silver, or a combination thereof. In some examples, the cladding material comprises copper. In some examples, the cladding material comprises silver.

Further provided herein, is a method of making a multifilamentary cable comprising two or more cryogenic wires, each of the two or more cryogenic wires independently being made by any of the methods disclosed herein, the method comprising binding the two or more cryogenic wires together.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

The accompanying figures, which are incorporated in and constitute a part of this specification, illustrate several aspects of the disclosure, and together with the description, serve to explain the principles of the disclosure.

FIG. 1 shows the conductivity per unit density of copper, aluminum, lithium, sodium, potassium, beryllium, magnesium, calcium, and titanium.

FIG. 2 shows the ratio of weight/resistance between lithium and copper conductor as a function of the fill ratio of lithium.

FIG. 3A-FIG. 3C show the calculations for resistance and mass. FIG. 3A shows the value of “a”, as used in the equations of FIG. 3B and FIG. 3C. FIG. 3B shows the calculation of resistance. FIG. 3B shows the calculation of mass.

FIG. 4 shows a schematic illustration of the vacuum casting process, which is performed in an inert gas atmosphere (1). The casting process includes the pipe made of a malleable, ductile metal of high melting point (2), a hose to pull in molten metal from the crucible (3), a heater to increase the temperature of the pipe (4), and a crucible (5) holding a molten metal of a high conductivity per unit density (6).

FIG. 5 shows a schematic illustration of a wire with a small cross sectional area and long length, as processed via calendaring, drawing, and annealing. The outer conductor area (1) includes malleable, ductile metal, wherein the metal can be copper, aluminum, or silver. The inner conductor area (2) includes metal of high conductivity-to-density ratio, wherein the metal can include lithium, calcium, or sodium.

FIG. 6 shows a schematic illustration of using calendar rollers to reduce the wire size. The original thick, annealed wire (1) is drawn through the calendar rollers (2) by a continuous pulling force (3) to result in the thin, long wire (4).

FIG. 7 shows an exemplary process of drawing the annealed wire (3) through a hardened, round die (1) to reduce the wire diameter and increase its length. The continuous pulling force (2) results in a thin, long, wire after drawing (4).

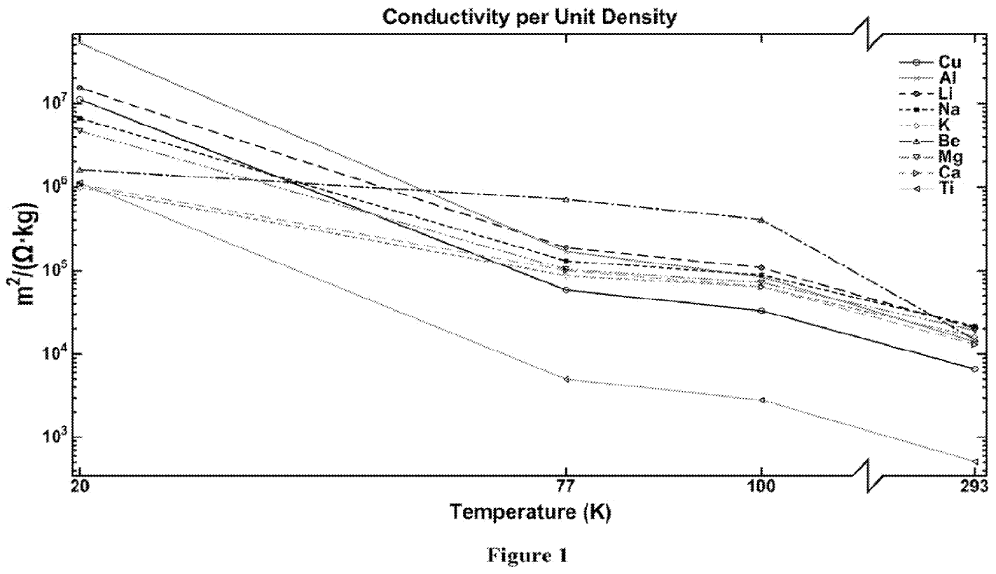

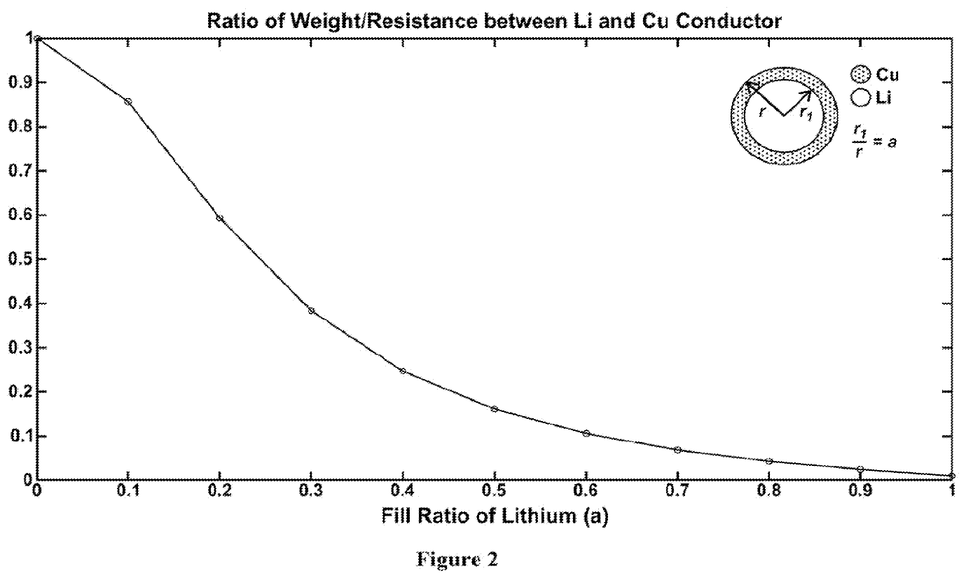

### DETAILED DESCRIPTION

The materials and methods described herein may be understood more readily by reference to the following detailed description of specific aspects of the disclosed subject matter and the Examples included therein.

Before the present materials and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

As can be apparent to those of skill in the art upon reading this disclosure, each of the individual embodiments described and illustrated herein has discrete components and features which may be readily separated from or combined with the features of any of the other several embodiments without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### General Definitions

In this specification and in the claims that follow, reference will be made to a number of terms, which shall be defined to have the following meanings.

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.”

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

“Exemplary” means “an example of” and is not intended to convey an indication of a preferred or ideal embodiment. “Such as” is not used in a restrictive sense, but for explanatory purposes.

Values can be expressed herein as an “average” value. “Average” generally refers to the statistical mean value.

By “substantially” is meant within 5%, e.g., within 4%, 3%, 2%, or 1%.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

As used herein in the specification and claims, the terms “conduit” and “tube” are used interchangeably and refer to a structure that can be used to direct flow of a gas or liquid.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

### Cryogenic Wires

Disclosed herein are cryogenic wires and methods of making and use thereof.

Cryogenic wires have a lower thermal conductivity, and high electrical resistivity, than other wires (such as copper wires). Because of this, cryogenic wires can be used at cryogenic temperatures without a decrease in their electrical performance. Cryogenic temperatures, as used herein, refers to temperatures from 0 Kelvin (K) to 150 K. For example, a cryogenic temperature can be 0 K or more (e.g., 5 K or more, 10 K or more, 15 K or more, 20 K or more, 25 K or more, 30 K or more, 35 K or more, 40 K or more, 45 K or more, 50 K or more, 55 K or more, 60 K or more, 65 K or more, 70 K or more, 75 K or more, 80 K or more, 85 K or more, 90 K or more, 95 K or more, 100 K or more, 110 K or more, 115 K or more, 120 K or more, 125 K or more, 130 K or more, 135 K or more, 140 K or more, or 145 K or more). In some examples, a cryogenic temperature can be 150K or less (e.g., 145 K or less, 140 K or less, 135 K or less, 130 K or less, 125 K or less, 120 K or less, 115 K or less, 110 K or less, 105 K or less, 100 K or less, 95 K or less, 90 K or less, 85 K or less, 80 K or less, 75 K or less, 70 K or less, 65 K or less, 60 K or less, 55 K or less, 50 K or less, 45 K or less, 40 K or less, 35 K or less, 30 K or less, 25 K or less, 20 K or less, 15 K or less, 10 K or less, or 5 K or less). The cryogenic temperature can range from any of the minimum values described above to any of the maximum values described above. For example, the cryogenic temperature can be from 0 K to 150 K (e.g., from 0 K to 75 K, from 75 K to 150 K, from 0 K to 50 K, from 50 K to 100 K, from 100 K to 150 K, from 0 K to 120 K, or from 0 K to 100 K).

Cryogenic wires allow for extremely high current with minimal electrical losses, e.g., at cryogenic temperatures. Cryogenic wires are made to be used in low temperatures and can be applied in areas such as electric power transmission or electric power distribution, particularly when high gravimetric power density is needed. Further, cryogenic wires can be used for inductors or transformer windings in cryogenic power electronics. Other applications of cryogenic wires include cryogenic microwave cables, cryogenic radio frequency (RF) cables, cryogenic multi-channel ribbon cable, quantum computers, and quantum internet applications.

For example, disclosed herein are cryogenic wires extending from a first end to a second end opposite and axially spaced apart from the first end, the cryogenic wire comprising a conductor having a mass density of 5000 kg/m³ or less; and a cladding material disposed around the conductor, the cladding material comprising a ductile and malleable metal.

The conductor can, for example, comprise a material having a mass density of 5000 kg/m³ or less (e.g., 4500 kg/m³ or less, 4000 kg/m³ or less, 3500 kg/m³ or less, 3000 kg/m³ or less, 2500 kg/m³ or less, 2250 kg/m³ or less, 2000 kg/m³ or less, 1750 kg/m³ or less, 1500 kg/m³ or less, 1400 kg/m³ or less, 1300 kg/m³ or less, 1200 kg/m³ or less, 1100 kg/m³ or less, 1000 kg/m³ or less, 750 kg/m³ or less, 500 kg/m³ or less, 400 kg/m³ or less, 300 kg/m³ or less, 200 kg/m³ or less, 100 kg/m³ or less, 90 kg/m³ or less, 80 kg/m³ or less, 70 kg/m³ or less, 60 kg/m³ or less, 50 kg/m³ or less, 45 kg/m³ or less, 40 kg/m³ or less, 35 kg/m³ or less, 30 kg/m³ or less, 25 kg/m³ or less, 20 kg/m³ or less, 15 kg/m³ or less, 10 kg/m³ or less, 5 kg/m³ or less, or 1 kg/m³ or less). In some examples the conductor can comprise a metal (e.g., a pure metal or an alloy). In some examples, the conductor can comprise lithium, beryllium, calcium, sodium, potassium, magnesium, titanium, or a combination thereof. In some examples, the conductor can comprise an alloy comprising lithium, beryllium, calcium, sodium, potassium, magnesium, titanium, or a combination thereof. The conductor having a mass density of 5000 kg/m³ or less can, in certain examples, have improved electrical performance at low temperatures when compared with other conductors (e.g., of higher mass density).

In some examples, the conductor can comprise lithium, beryllium, calcium, sodium, magnesium, titanium, or a combination thereof. In further examples, the conductor can comprise lithium or an alloy thereof, beryllium or an alloy thereof, calcium or an alloy thereof, sodium or an alloy thereof, magnesium or an alloy thereof, titanium or an alloy thereof, or a combination thereof.

In some examples, the conductor can have an electrical conductivity per unit density of 500 S·m²/kg or more at room temperature (e.g., 550 S·m²/kg or more; 600 S·m²/kg or more; 650 S·m²/kg or more; 700 S·m²/kg or more; 750 S·m²/kg or more; 800 S·m²/kg or more; 850 S·m²/kg or more; 900 S·m²/kg or more; 950 S·m²/kg or more; 1,000 S·m²/kg or more; 1,100 S·m²/kg or more; 1,200 S·m²/kg or more; 1,300 S·m²/kg or more; 1,400 S·m²/kg or more; 1,500 S·m²/kg or more; 1,750 S·m²/kg or more; 2,000 S·m²/kg or more; 2,250 S·m²/kg or more; 2,500 S·m²/kg or more; 3,000 S·m²/kg or more; 3,500 S·m²/kg or more; 4,000 S·m²/kg or more; 4,500 S·m²/kg or more; 5,000 S·m²/kg or more; 6,000 S·m²/kg or more; 7,000 S·m²/kg or more; 8,000 S·m²/kg or more; 9,000 S·m²/kg or more; 10,000 S· m²/kg or more; 12,500 S·m²/kg or more; 15,000 S· m²/kg or more; 17,500 S·m²/kg or more; or 20,000 S·m²/kg or more). In some examples, the conductor can have an electrical conductivity per unit density of 22,000 S· m²/kg or less at room temperature (e.g., 21,000 S·m²/kg or less; 20,000 S· m²/kg or less; 17,500 S·m²/kg or less; 15,000 S·m²/kg or less; 12,500 S·m²/kg or less; 10,000 S·m²/kg or less; 9,000 S·m²/kg or less; 8,000 S·m²/kg or less; 7,000 S·m²/kg or less; 6,000 S·m²/kg or less; 5,000 S·m²/kg or less; 4,500 S·m²/kg or less; 4,000 S·m²/kg or less; 3,500 S·m²/kg or less; 3,000 S·m²/kg or less; 2,500 S·m²/kg or less; 2,250 S·m²/kg or less; 2,000 S·m²/kg or less; 1,750 S·m²/kg or less; 1,500 S·m²/kg or less; 1,400 S·m²/kg or less; 1,300 S·m²/kg or less; 1,200 S·m²/kg or less; 1,100 S·m²/kg or less; 1,000 S·m²/kg or less; 950 S·m²/kg or less; 900 S·m²/kg or less; 850 S·m²/kg or less; 800 S·m²/kg or less; 750 S·m²/kg or less; 700 S·m²/kg or less; 650 S·m²/kg or less; S·m²/kg or less; 600 S·m²/kg or less; or 550 S·m²/kg or less). The electrical conductivity per unit density of the conductor at room temperature can range from any of the minimum values described above to any of the maximum values described above. For example, the conductor can have an electrical conductivity per unity density of from 500 to 22,000 S·m²/kg at room temperature (e.g., from 500 to 11,000 S·m²/kg; from 11,000 to 22,000 S·m²/kg; from 500 to 5,000 S·m²/kg; from 5,000 to 10,000 S·m²/kg; from 10,000 to 15,000 S·m²/kg; from 15,000 to 22,000 S·m²/kg; from 500 to 21,000 S·m²/kg; from 500 to 20,000 S·m²/kg; from 500 to 15,000 S·m²/kg; from 500 to 10,000 S·m²/kg; from 600 to 22,000 S·m²/kg; from 750 to 22,000 S·m²/kg; from 1,000 to 22,000 S·m²/kg; from 10,000 to 22,000 S·m²/kg; from 600 to 21,000 S·m²/kg; from 750 to 20,000 S·m²/kg; or from 6,5000 to 21,000 S·m²/kg).

Room temperature, as used herein, refers to temperatures from 293 K to 300 K. For example, room temperature can be 293 K or more (e.g., 294 K or more, 295 K or more, 296 K or more, 297 K or more, 298 K or more, or 299 K or more). In some examples, room temperature can be 300 K or less (e.g., 299 K or less, 298 K or less, 297 K or less, 296 K or less, 295 K or less, or 294 K or less). Room temperature can range from any of the minimum values described above to any of the maximum values described above. For example, room temperature can be from 293 K to 300 K (e.g., from 293 K to 296 K, from 296 K to 300 K, from 293 K to 295 K, from 295 K to 297 K, from 297 K to 300 K, from 293 K to 294 K, from 294 K to 295 K, from 295 K to 296 K, from 296 K to 297 K, from 297 K to 298 K, from 298 K to 299 K, from 299 K to 300 K, from 293 K to 299 K, from 293 K to 298 K, from 294 K to 300 K, from 295 K to 300 K, from 294 K to 299 K, or from 295 K to 298 K).

In some examples, the conductor can have an electrical conductivity per unit density of 2,500 S·m²/kg or more at 100 K (e.g., 3,000 S· m²/kg or more; 3,500 S· m²/kg or more; 4,000 S·m²/kg or more; 4,500 S·m²/kg or more; 5,000 S·m²/kg or more; 6,000 S·m²/kg or more; 7,000 S·m²/kg or more; 8,000 S·m²/kg or more; 9,000 S·m²/kg or more; 10,000 S·m²/kg or more; 12,500 S· m²/kg or more; 15,000 S·m²/kg or more; 17,500 S·m²/kg or more; 20,000 S·m²/kg or more; 22,500 S·m²/kg or more; 25,000 S·m²/kg or more; 30,000 S·m²/kg or more; 35,000 S·m²/kg or more; 40,000 S· m²/kg or more; 45,000 S·m²/kg or more; 50,000 S·m²/kg or more; 60,000 S·m²/kg or more; 70,000 S·m²/kg or more; 80,000 S·m²/kg or more; 90,000 S·m²/kg or more; 100,000 S·m²/kg or more; 125,000 S·m²/kg or more; 150,000 S·m²/kg or more; 175,000 S·m²/kg or more; 200,000 S·m²/kg or more; 225,000 S·m²/kg or more; 250,000 S· m²/kg or more; 275,000 S·m²/kg or more; 300,000 S·m²/kg or more; 325,000 S· m²/kg or more; 350,000 S·m²/kg or more; or 375,000 S·m²/kg or more). In some examples, the conductor can have an electrical conductivity per unit density of 410,000 S·m²/kg or less at 100 K (e.g., 400,000 S·m²/kg or less; 375,000 S·m²/kg or less; 350,000 S·m²/kg or less; 325,000 S·m²/kg or less; 300,000 S·m²/kg or less; 275,000 S·m²/kg or less; 250,000 S·m²/kg or less; 225,000 S·m²/kg or less; 200,000 S· m²/kg or less; 175,000 S·m²/kg or less; 150,000 S·m²/kg or less; 125,000 S·m²/kg or less; 100,000 S·m²/kg or less; 90,000 S·m²/kg or less; 80,000 S· m²/kg or less; 70,000 S·m²/kg or less; 60,000 S· m²/kg or less; 50,000 S· m²/kg or less; 45,000 S·m²/kg or less; 40,000 S·m²/kg or less; 35,000 S· m²/kg or less; 30,000 S· m²/kg or less; 25,000 S·m²/kg or less; 22,5000 S· m²/kg or less; 20,000 S·m²/kg or less; 17,500 S·m²/kg or less; 15,000 S·m²/kg or less; 12,500 S·m²/kg or less; 10,000 S·m²/kg or less; 9,000 S·m²/kg or less; 8,000 S· m²/kg or less; 7,000 S·m²/kg or less; 6,000 S·m²/kg or less; 5,000 S·m²/kg or less; 4,500 S·m²/kg or less; 4,000 S· m²/kg or less; 3,500 S·m²/kg or less; or 3,000 S·m²/kg or less). The electrical conductivity per unity density of the conductor at 100 K can range from any of the minimum values described above to any of the maximum values described above. For example, the conductor can have an electrical conductivity per unity density of from 2,500 to 410,000 S·m²/kg at 100 K (e.g., from 2,500 to 200,000 S·m²/kg; from 200,000 to 410,000 S·m²/kg; from 2,500 to 25,000 S·m²/kg; from 25,000 to 250,000 S·m²/kg; from 250,000 to 410,000 S· m²/kg; from 3,000 to 410,000 S·m²/kg; from 4,000 to 410,000 S·m²/kg; from 5,000 to 410,000 S·m²/kg; from 10,000 to 410,000 S·m²/kg; from 20,000 to 410,000 S·m²/kg; from 2,500 to 400,000 S·m²/kg; from 2,500 to 375,000 S·m²/kg; from 2,500 to 350,000 S·m²/kg; from 2,5000 to 325,000 S·m²/kg; from 3,000 to 400,000 S·m²/kg; from 4,000 to 375,000 S·m²/kg; or from 32,000 to 410,000 S·m²/kg).

In certain examples, the conductor can have an electrical conductivity per unit density of 4,500 S· m²/kg or more at 77 K (e.g., 5,000 S·m²/kg or more; 6,000 S·m²/kg or more; 7,000 S·m²/kg or more; 8,000 S·m²/kg or more; 9,000 S·m²/kg or more; 10,000 S·m²/kg or more; 12,500 S· m²/kg or more; 15,000 S·m²/kg or more; 17,500 S·m²/kg or more; 20,000 S·m²/kg or more; 22,500 S· m²/kg or more; 25,000 S·m²/kg or more; 30,000 S·m²/kg or more; 35,000 S· m²/kg or more; 40,000 S·m²/kg or more; 45,000 S·m²/kg or more; 50,000 S·m²/kg or more; 60,000 S·m²/kg or more; 70,000 S·m²/kg or more; 80,000 S·m²/kg or more; 90,000 S·m²/kg or more; 100,000 S·m²/kg or more; 125,000 S·m²/kg or more; 150,000 S·m²/kg or more; 175,000 S· m²/kg or more; 200,000 S·m²/kg or more; 225,000 S·m²/kg or more; 250,000 S·m²/kg or more; 275,000 S·m²/kg or more; 300,000 S·m²/kg or more; 325,000 S·m²/kg or more; 350,000 S· m²/kg or more; 375,000 S·m²/kg or more; 400,000 S·m²/kg or more; 450,000 S·m²/kg or more; 500,000 S· m²/kg or more; 550,000 S·m²/kg or more; 600,000 S·m²/kg or more; 650,000 S·m²/kg or more; or 700,000 S·m²/kg or more). In some examples, the conductor can have an electrical conductivity per unity density of 750,000 S·m²/kg or less at 77 K (e.g., 700,000 S·m²/kg or less; 650,000 S·m²/kg or less; 600,000 S·m²/kg or less; 550,000 S·m²/kg or less; 500,000 S·m²/kg or less; 450,000 S·m²/kg or less; 400,000 S·m²/kg or less; 375,000 S·m²/kg or less; 400,000 S·m²/kg or less; 375,000 S·m²/kg or less; 350,000 S· m²/kg or less; 325,000 S·m²/kg or less; 300,000 S·m²/kg or less; 275,000 S·m²/kg or less; 250,000 S·m²/kg or less; 225,000 S·m²/kg or less; 200,000 S·m²/kg or less; 175,000 S·m²/kg or less; 150,000 S·m²/kg or less; 125,000 S·m²/kg or less; 100,000 S·m²/kg or less; 90,000 S·m²/kg or less; 80,000 S·m²/kg or less; 70,000 S·m²/kg or less; 60,000 S·m²/kg or less; 50,000 S·m²/kg or less; 45,000 S· m²/kg or less; 40,000 S·m²/kg or less; 35,000 S· m²/kg or less; 30,000 S·m²/kg or less; 25,000 S·m²/kg or less; 22,5000 S·m²/kg or less; 20,000 S·m²/kg or less; 17,500 S·m²/kg or less; 15,000 S·m²/kg or less; 12,500 S·m²/kg or less; 10,000 S·m²/kg or less; 9,000 S·m²/kg or less; 8,000 S·m²/kg or less; 7,000 S·m²/kg or less; 6,000 S·m²/kg or less; or 5,000 S·m²/kg or less). The conductivity per unity density of the conductor at 77 k can range from any of the minimum values described above to any of the maximum values described above. For example, the conductor can have a conductivity per unity density of from 4,500 to 750,000 S·m²/kg at 77 K (e.g., from 4,500 to 375,000 S·m²/kg; from 375,000 to 750,000 S· m²/kg; from 4,500 to 45,000 S·m²/kg; from 45,000 to 750,000 S·m²/kg; from 4,500 to 10,000 S·m²/kg; from 10,000 to 100,000 S·m²/kg; from 100,000 to 750,000 S·m²/kg; from 5000 to 750,000 S·m²/kg; from 7,500 to 750,000 S·m²/kg; from 10,000 to 750,000 S· m²/kg; from 4,500 to 700,000 S·m²/kg; from 4,500 to 650,000 S·m²/kg; from 4,500 to 600,000 S·m²/kg; from 5,000 to 700,000 S·m²/kg; from 7,500 to 500,000 S·m²/kg; or from 58,000 to 750,000 S·m²/kg).

In specific examples, the conductor can have an electrical conductivity per unit density of 950,000 or more at 20 K (e.g., 1,000,000 S·m²/kg or more; 1,100,000 S·m²/kg or more; 1,200,000 S·m²/kg or more; 1,300,000 S·m²/kg or more; 1,400,000 S·m²/kg or more; 1,500,000 S·m²/kg or more; 1,750,000 S·m²/kg or more; 2,000,000 S·m²/kg or more; 2,250,000 S·m²/kg or more; 2,500,000 S·m²/kg or more; 3,000,000 S·m²/kg or more; 3,500,000 S· m²/kg or more; 4,000,000 S·m²/kg or more; 4,500,000 S·m²/kg or more; 5,000,000 S·m²/kg or more; 6,000,000 S·m²/kg or more; 7,000,000 S·m²/kg or more; 8,000,000 S· m²/kg or more; 9,000,000 S·m²/kg or more; 10,000,000 S·m²/kg or more; 11,000,000 S·m²/kg or more; 12,000,000 S·m²/kg or more; 13,000,000 S·m²/kg or more; 14,000,000 S· m²/kg or more; or 15,000,000 S·m²/kg or more). In some examples, the conductor can have an electrical conductivity per unity density of 16,000,000,000,000 S· m²/kg or less at 20 K (e.g., 15,000,000 S·m²/kg or less; 14,000,000 S·m²/kg or less; 13,000,000 S·m²/kg or less; 12,000,000 S·m²/kg or less; 11,000,000 S·m²/kg or less; 10,000,000 S·m²/kg or less; 9,000,000 S·m²/kg or less; 8,000,000 S·m²/kg or less; 7,000,000 S·m²/kg or less; 6,000,000 S·m²/kg or less; 5,000,000 S·m²/kg or less; 4,500,000 S·m²/kg or less; 4,000,000 S· m²/kg or less; 3,500,000 S·m²/kg or less; 3,000,000 S·m²/kg or less; 2,500,000 S·m²/kg or less; 2,250,000 S·m²/kg or less; 2,000,000 S·m²/kg or less; 1,750,000 S· m²/kg or less; 1,500,000 S·m²/kg or less; 1,400,000 S· m²/kg or less; 1,300,000 S·m²/kg or less; 1,200,000 S·m²/kg or less; 1,100,000 S·m²/kg or less; or 1,000,000 S·m²/kg or less). The electrical conductivity per unity density of the conductor at 20 K can range from any of the minimum values described above to any of the maximum values described above. For example, the conductor can have an electrical conductivity per unity density of from 950,000 to 16,000,000 S·m²/kg at 20 K (e.g., from 950,000 to 8,000,000 S· m²/kg; from 8,000,000 to 16,000,000 S· m²/kg; from 950,000 to 5,000,000 S· m²/kg; from 5,000,000 to 10,000,000 S·m²/kg; from 10,000,000 to 16,000,000 S·m²/kg; from 950,000 to 15,000,000 S·m²/kg; from 950,000 to 14,000,000 S· m²/kg; from 950,000 to 13,000,000 S·m²/kg; from 950,000 to 12,000,000 S· m²/kg; from 950,000 to 11,000,000 S·m²/kg; from 950,000 to 10,000,000 S·m²/kg; from 1,000,000 to 16,000,000 S·m²/kg; from 1,100,000 to 16,000,000 S·m²/kg; from 1,200,000 to 16,000,000 S·m²/kg; from 1,500,000 to 16,000,000 S·m²/kg; from 2,000,000 to 16,000,000 S·m²/kg; from 1,000,000 to 15,000,000 S·m²/kg; from 1,100,000 to 14,000,000 S·m²/kg; or from 1,100,000 to 16,000,000 S·m²/kg).

The cladding material can comprise any suitably ductile and malleable metal. For example, the cladding material can comprise a metal having a ductility as measured by the elongation percentage at break of 0.1% or more (e.g., 0.15% or more, 0.2% or more, 0.25% or more, 0.3% or more, 0.35% or more, 0.4% or more, 0.45% or more, or 0.5% or more). Malleability describes the ability of a metal ability to be distorted below compression. Ductile and malleable metals allow for the wire to be drawn using wire drawing techniques, tools, and facilities. Ductile and malleable metals can be used in standard joining techniques such as soldering and crimping.

Examples of suitable cladding materials include, but are not limited to, aluminum, copper, gold, nickel alloys, niobium-titanium, platinum, steel, tantalum, lead, tin, iron, manganese, and combinations thereof. The cladding material can also include alloys of the materials disclosed herein. In some examples, the cladding material can comprise silver, copper, or a combination thereof. In some examples, the cladding material can comprise copper. In some examples, the cladding material can comprise silver.

Electrical resistivity (ρ) is a fundamental property of a material that measures how strongly it resists electric current. A low resistivity indicates a material that readily allows electric current. Electrical resistivity is dependent on temperature and has the unit ohm (Ω).

In some examples, the cryogenic wire can have an electrical resistivity of 1.6×10⁻⁸ Ω·m or more at room temperature (e.g., 1.7×10⁻⁷ Ω·m or more; 1.8×10⁻⁷ Ω·m or more; 1.9×10⁻⁷ Ω·m or more; 2×10⁻⁸ Ω·m or more; 2.5×10⁻⁷ Ω·m or more; 3×10⁻⁷ Ω·m or more; 3.5×10⁻⁷ Ω·m or more; 4×10⁻⁷ Ω·m or more; 4.5×10⁻⁷ Ω·m or more; 5×10⁻⁸ Ω·m or more; 6×10⁻⁷ Ω·m or more; 7×10⁻⁷ Ω·m or more; 8×10⁻⁷ Ω·m or more; 9×10⁻⁷ Ω·m or more; 1×10⁻⁷ Ω·m or more; 1.25×10⁻⁷ Ω·m or more; 1.5×10⁻⁷ Ω·m or more; 1.75×10⁻⁷ Ω·m or more; 2×10⁻⁷ Ω·m or more; 2.5×10⁻⁷ Ω·m or more; 3×10⁻⁷ Ω·m or more; 3.5×10⁻⁷ Ω·m or more; or 4×10⁻⁷ Ω·m or more). In some examples, the cryogenic wire can have an electrical resistivity of 4.5×10⁻⁷ Ω·m or less at room temperature (e.g., 4×10⁻⁷ Ω·m or less; 3.5×10⁻⁷ Ω·m or less; 3×10⁻⁷ Ω·m or less; 2.5×10⁻⁷ Ω·m or less; 2×10⁻⁷ Ω·m or less; 1.75×10⁻⁷ Ω·m or less; 1.5×10⁻⁷ Ω·m or less; 1.25×10⁻⁷ Ω·m or less; 1×10⁻⁷ Ω·m or less; 9×10⁻⁷ Ω·m or less; 8×10⁻⁷ Ω·m or less; 7×10⁻⁷ Ω·m or less; 6×10⁻⁷ Ω·m or less; 5×10⁻⁷ Ω·m or less; 4.5×10⁻⁷ Ω·m or less; 4×10⁻⁸ Ω·m or less; 3.5×10⁻⁷ Ω·m or less; 3×10⁻⁸ Ω·m or less; 2.5×10⁻⁷ Ω·m or less; or 2×10⁻⁸ Ω·m or less). The electrical resistivity of the cryogenic wire at room temperature can range from any of the minimum values described above to any of the maximum values described above. For example, from 1.6×10⁻⁷ to 4.5×10⁻⁷ Ω·m at room temperature (e.g., from 1.6×10⁻⁸ to 5×10⁻⁸ Ω·m, from 5×10⁻⁷ to 1×10⁻⁷ Ω·m, from 1×10⁻⁷ to 4.5×10⁻⁷ Ω·m, from 2×10⁻⁷ to 4.5×10⁻⁷ Ω·m, from 2.5×10⁻⁷ to 4.5×10⁻⁷ Ω·m, from 3×10⁻⁷ to 4.5×10⁻⁷ Ω·m, from 3.2×10⁻⁸ to 4.5×10⁻⁷ Ω·m, from 4×10⁻⁷ to 4.5×10⁻⁷ Ω·m, from 5×10⁻⁷ to 4.5×10⁻⁷ Ω·m, from 1.6×10⁻⁷ to 4×10⁻⁷ Ω·m, from 1.6×10⁻⁷ to 3.5×10⁻⁷ Ω·m, from 1.6×10⁻⁷ to 3×10⁻⁷ Ω·m, from 1.6×10⁻⁷ to 2.5×10⁻⁷ Ω·m, from 1.6×10⁻⁷ to 2×10⁻⁷ Ω·m, from 1.6×10⁻⁷ to 1×10⁻⁷ Ω·m, from 1.7×10⁻⁷ to 4×10⁻⁷ Ω·m, from 1.8×10⁻⁷ to 3.5×10⁻⁷ Ω·m, from 1.9×10⁻⁷ to 3×10⁻⁷ Ω·m, from 2×10⁻⁸ to 2×10⁻⁷ Ω·m, or from 3.2×10⁻⁸ to 1.7×10⁻⁸ Ω·m).

In some examples, the cryogenic wire can have an electrical resistivity of 1.0×10⁻⁹ Ω·m or more at 100 K (e.g., 1.5×10⁻⁹ Ω·m or more, 2×10⁻⁹ Ω·m or more, 2.5×10⁻⁹ Ω·m or more, 3×10⁻⁹ Ω·m or more, 3.5×10⁻⁹ Ω·m or more, 4×10⁻⁹ Ω·m or more, 4.5×10⁻⁹ Ω·m or more, 5×10⁻⁹ Ω·m or more, 6×10⁻⁹ Ω·m or more, 7×10⁻⁹ Ω·m or more, 8×10⁻⁹ Ω·m or more, 9×10⁻⁹ Ω·m or more, 1×10⁻⁷ Ω·m or more, 1.25×10⁻⁷ Ω·m or more, 1.5×10⁻⁷ Ω·m or more, 1.75×10⁻⁸ Ω·m or more, 2×10⁻⁸ Ω·m or more, 2.5×10⁻⁸ Ω·m or more, 3×10⁻⁷ Ω·m or more, 3.5×10⁻⁸ Ω·m or more, 4×10⁻⁷ Ω·m or more, 4.5×10⁻⁷ Ω·m or more, 5×10⁻⁷ Ω·m or more, 6×10⁻⁷ Ω·m or more, or 7×10⁻⁷ Ω·m or more). In some examples, the cryogenic wire can have an electrical resistivity of 8.0×10⁻⁷ Ω·m or less at 100 K (e.g., 7×10⁻⁷ Ω·m or less; 6×10⁻⁸ Ω·m or less; 5×10⁻⁷ Ω·m or less; 4.5×10⁻⁷ Ω·m or less; 4×10⁻⁷ Ω·m or less; 3.5×10⁻⁷ Ω·m or less; 3×10⁻⁷ Ω·m or less; 2.5×10⁻⁷ Ω·m or less; 2×10⁻⁷ Ω·m or less; 1.75×10⁻⁷ Ω·m or less; 1.5×10⁻⁸ Ω·m or less; 1.25×10⁻⁷ Ω·m or less; 1×10⁻⁷ Ω·m or less; 9×10⁻⁹ Ω·m or less; 8×10⁻⁹ Ω·m or less; 7×10⁻⁹ Ω·m or less; 6×10⁻⁹ Ω·m or less; 5×10⁻⁹ Ω·m or less; 4.5×10⁻⁹ Ω·m or less; 4×10⁻⁹ Ω·m or less; 3.5×10⁻⁹ Ω·m or less; 3×10⁻⁹ Ω·m or less; 2.5×10⁻⁹ Ω·m or less; or 2×10⁻⁹ Ω·m or less). The electrical resistivity of the cryogenic wire at 100 K can range from any of the minimum values described above to any of the maximum values described above. For example, the cryogenic wire can have an electrical resistivity of from 1.0×10⁻⁹ to 8.0×10⁻⁸ Ω·m at 100 K (e.g., from 1×10⁻⁹ to 1×10⁻⁸ Ω·m, from 1×10⁻⁷ to 8×10⁻⁸ Ω·m, from 1×10⁻⁹ to 5×10⁻⁹ Ω·m, from 5×10⁻⁹ to 1×10⁻⁷ Ω·m, from 1×10⁻⁷ to 4×10⁻⁷ Ω·m, from 4×10⁻⁷ to 8×10⁻⁸ Ω·m, from 1.0×10⁻⁹ to 7×10⁻⁷ Ω·m, from 1.0×10⁻⁹ to 6×10⁻⁷ Ω·m, from 1.0×10⁻⁹ to 5×10⁻⁷ Ω·m, from 1.0×10⁻⁹ to 2.5×10⁻⁷ Ω·m, from 1.5×10⁻⁹ to 8.0×10⁻⁷ Ω·m, from 2×10⁻⁹ to 8.0×10⁻⁷ Ω·m, from 2.5×10⁻⁹ to 8.0×10⁻⁷ Ω·m, from 3×10⁻⁹ to 8.0×10⁻⁷ Ω·m, from 4×10⁻⁹ to 8.0×10⁻⁷ Ω·m, from 5×10⁻⁹ to 8.0×10⁻⁷ Ω·m, from 1.5×10⁻⁹ to 7.0×10⁻⁷ Ω·m, from 2×10⁻⁹ to 6.0×10⁻⁷ Ω·m, from 2.5×10⁻⁹ to 5.0×10⁻⁷ Ω·m, or from 1.0×10⁻⁹ to 3.4×10⁻⁹ Ω·m).

In some examples, the cryogenic wire can have an electrical resistivity of 7.3×10⁻¹⁰ Ω·m or more at 77 K (e.g., 7.5×10⁻¹⁰ Ω·m or more, 8×10⁻¹⁰ Ω·m or more, 8.5×10⁻¹⁰ Ω·m or more, 9×10⁻¹⁰ Ω·m or more, 9.5×10⁻¹⁰ Ω·m or more, 1×10⁻⁹ Ω·m or more, 1.25×10⁻⁹ Ω·m or more, 1.5×10⁻⁹ Ω·m or more, 1.75×10⁻⁹ Ω·m or more, 2×10⁻⁹ Ω·m or more, 2.5×10⁻⁹ Ω·m or more, 3×10⁻⁹ Ω·m or more, 3.5×10⁻⁹ Ω·m or more, 4×10⁻⁹ Ω·m or more, 4.5×10⁻⁹ Ω·m or more, 5×10⁻⁹ Ω·m or more, 6×10⁻⁹ Ω·m or more, 7×10⁻⁹ Ω·m or more, 8×10⁻⁹ Ω·m or more, 9×10⁻⁹ Ω·m or more, 1×10⁻⁸ Ω·m or more, 1.25×10⁻⁸ Ω·m or more, 1.5×10⁻⁷ Ω·m or more, 1.75×10⁻⁷ Ω·m or more, 2×10⁻⁸ Ω·m or more, 2.5×10⁻⁷ Ω·m or more, 3×10⁻⁷ Ω·m or more, 3.5×10⁻⁷ Ω·m or more, or 4×10⁻⁷ Ω·m or more). In some examples, the cryogenic wire can have an electrical resistivity of 4.7×10⁻⁷ Ω·m or less at 77 K (e.g., 4.5×10⁻⁷ Ω·m or less, 4×10⁻⁸ Ω·m or less, 3.5×10⁻⁷ Ω·m or less, 3×10⁻⁷ Ω·m or less, 2.5×10⁻⁷ Ω·m or less, 2×10⁻⁸ Ω·m or less, 1.75×10⁻⁷ Ω·m or less, 1.5×10⁻⁷ Ω·m or less, 1.25×10⁻⁷ Ω·m or less, 1×10⁻⁷ Ω·m or less, 9×10⁻⁹ Ω·m or less, 8×10⁻⁹ Ω·m or less, 7×10⁻⁹ Ω·m or less, 6×10⁻⁹ Ω·m or less, 5×10⁻⁹ Ω·m or less, 4.5×10⁻⁹ Ω·m or less, 4×10⁻⁹ Ω·m or less, 3.5×10⁻⁹ Ω·m or less, 3×10⁻⁹ Ω·m or less, 2.5×10⁻⁹ Ω·m or less, 2×10⁻⁹ Ω·m or less, 1.75×10⁻⁹ Ω·m or less, 1.5×10⁻⁹ Ω·m or less, 1.25×10⁻⁹ Ω·m or less, 1×10⁻⁹ Ω·m or less, 9.5×10⁻¹⁰ Ω·m or less, 9×10⁻¹⁰ Ω·m or less, 8.5×10⁻¹⁰ Ω·m or less, or 8×10⁻¹⁰ Ω·m or less). The electrical resistivity of the cryogenic wire can range from any of the minimum values described above to any of the maximum values described above. For examples, the cryogenic wire can have an electrical resistivity of from 7.3×10⁻¹⁰ to 4.7×10⁻⁷ Ω·m at 77 K (e.g., from 7.3×10⁻¹⁰ to 5×10⁻⁹ Ω·m, from 5×10⁻⁹ to 4.7×10⁻⁷ Ω·m, from 7.3×10⁻¹⁰ to 1×10⁻⁹ Ω·m, from 1×10⁻⁹ to 5×10⁻⁹ Ω·m, from 5×10⁻⁹ to 1×10⁻⁸ Ω·m, from 1×10⁻⁷ to 4.7×10⁻⁷ Ω·m, from 7.3×10⁻¹⁰ to 4×10⁻⁸ Ω·m, from 7.3×10⁻¹⁰ to 2×10⁻⁷ Ω·m, from 7.3×10⁻¹⁰ to 1×10⁻⁷ Ω·m from 7.3×10⁻¹⁰ to 9×10⁻⁹ Ω·m, from 7.3×10⁻¹⁰ to 7×10⁻⁹ Ω·m, from 7.5×10⁻¹⁰ to 4.7×10⁻⁷ Ω·m, from 8×10⁻¹⁰ to 4.7×10⁻⁸ Ω·m, from 9×10⁻¹⁰ to 4.7×10⁻⁷ Ω·m, from 1×10⁻⁹ to 4.7×10⁻⁷ Ω·m, from 2.5×10⁻⁹ to 4.7×10⁻⁷ Ω·m, from 5×10⁻⁹ to 4.7×10⁻⁷ Ω·m, from 7.5×10⁻¹⁰ to 4×10⁻⁷ Ω·m, from 9×10⁻¹⁰ to 2×10⁻⁸ Ω·m, from 1×10⁻⁹ to 1×10⁻⁸ Ω·m, or from 7.3×10⁻¹⁰ to 1.9×10⁻⁹ Ω·m).

In some examples, the cryogenic wire can have an electrical resistivity of 7.0×10⁻¹² Ω·m or more at 20 K (e.g., 7.5×10⁻¹² Ω·m or more, 8×10⁻¹² Ω·m or more, 8.5×10⁻¹² Ω·m or more, 9×10⁻¹² Ω·m or more, 9.5×10⁻¹² Ω·m or more, 1×10⁻¹¹ Ω·m or more, 1.25×10⁻¹¹ Ω·m or more, 1.5×10⁻¹¹ Ω·m or more, 1.75×10⁻¹¹ Ω·m or more, 2×10⁻¹¹ Ω·m or more, 2.5×10⁻¹¹ Ω·m or more, 3×10⁻¹¹ Ω·m or more, 3.5×10⁻¹¹ Ω·m or more, 4×10⁻¹¹ Ω·m or more, 4.5×10⁻¹¹ Ω·m or more, 5×10⁻¹¹ Ω·m or more, 6×10⁻¹¹ Ω·m or more, 7×10⁻¹¹ Ω·m or more, 8×10⁻¹¹ Ω·m or more, 9×10⁻¹¹ Ω·m or more, 1.0×10⁻¹⁰ Ω·m or more, 1.5×10⁻¹⁰ Ω·m or more, 2××10⁻¹⁰ Ω·m or more, 2.5×10⁻¹⁰ Ω·m or more, 3×10⁻¹⁰ Ω·m or more, 3.5×10⁻¹⁰ Ω·m or more, 4×10⁻¹⁰ Ω·m or more, 4.5×10⁻¹⁰ Ω·m or more, 5×10⁻¹⁰ Ω·m or more, 6×10⁻¹⁰ Ω·m or more, 7×10⁻¹⁰ Ω·m or more, 8×10⁻¹⁰ Ω·m or more, 9×10⁻¹⁰ Ω·m or more, or 1×10⁻⁹ Ω·m or more). In some examples, the cryogenic wire can have an electrical resistivity of 1.5×10⁻⁹ Ω·m or less at 20 K (e.g., 1×10⁻⁹ Ω·m or less, 9×10⁻¹⁰ Ω·m or less, 8×10⁻¹⁰ Ω·m or less, 7×10⁻¹⁰ Ω·m or less, 6.5×10⁻¹⁰ Ω·m or less, 6×10⁻¹⁰ Ω·m or less, 5.5×10⁻¹⁰ Ω·m or less, 5×10⁻¹⁰ Ω·m or less, 4.5×10⁻¹⁰ Ω·m or less, 4×10⁻¹⁰ Ω·m or less, 3.5×10⁻¹⁰ Ω·m or less, 3×10⁻¹⁰ Ω·m or less, 2.5×10⁻¹⁰ Ω·m or less, 2×10⁻¹⁰ Ω·m or less, 1.5×10⁻¹⁰ Ω·m or less, 1×10⁻¹⁰ Ω·m or less, 9×10⁻¹¹ Ω·m or less, 8×10⁻¹¹ Ω·m or less, 7×10⁻¹¹ Ω·m or less, 6×10⁻¹¹ Ω·m or less, 5×10⁻¹¹ Ω·m or less, 4.5×10⁻¹¹ Ω·m or less, 4×10⁻¹¹ Ω·m or less, 3.5×10⁻¹¹ Ω·m or less, 3×10⁻¹¹ Ω·m or less, 2.5×10⁻¹¹ Ω·m or less, 2×10⁻¹¹ Ω·m or less, 1.5×10⁻¹¹ Ω·m or less, 1×10⁻¹¹ Ω·m or less, 9.5×10⁻¹² Ω·m or less, 9×10⁻¹² Ω·m or less, 8.5×10⁻¹² Ω·m or less, or 8×10⁻¹² Ω·m or less). The electrical resistivity of the cryogenic wire can range from any of the minimum values described above to any of the maximum values described above. For example, the cryogenic wire can have and electrical resistivity of from 7.0×10⁻¹² to 1.5×10⁻⁹ Ω·m at 20 K (e.g., from 7.0×10⁻¹² to 1.5×10⁻¹¹ Ω·m, from 1.5×10⁻¹¹ to 5×10⁻¹⁰ Ω·m, from 5×10⁻¹⁰ to 1.5×10⁻⁹ Ω·m, from 7.0×10⁻¹² to 1×10⁻⁹ Ω·m, from 7.0×10⁻¹² to 9×10⁻¹⁰ Ω·m, from 7.0×10⁻¹² to 7.5×10⁻¹⁰ Ω·m, from 7.0×10⁻¹² to 5×10⁻¹⁰ Ω·m, from 7.0×10⁻¹² to 2.5×10⁻¹⁰ Ω·m, from 8×10⁻¹² to 1.5×10⁻⁹ Ω·m, from 9×10⁻¹² to 1.5×10⁻⁹ Ω·m, from 1×10⁻¹¹ to 1.5×10⁻⁹ Ω·m, from 2.5×10⁻¹¹ to 1.5×10⁻⁹ Ω·m, from 5×10⁻¹¹ to 1.5×10⁻⁹ Ω·m, from 7.5×10⁻¹¹ to 1.5×10⁻⁹ Ω·m, from 1×10⁻¹⁰ to 1.5×10⁻⁹ Ω·m, from 7.5×10⁻¹² to 1×10⁻⁹ Ω·m, from 9×10⁻¹² to 9×10⁻¹⁰ Ω·m, from 1×10⁻¹¹ to 7.5×10⁻¹⁰ Ω·m, from 5×10⁻¹¹ to 5×10⁻¹⁰ Ω·m, from 7.0×10⁻¹² to 1×10⁻¹¹ Ω·m, or from 1.0×10⁻¹⁰ to 1.5×10⁻⁹ Ω·m).

Thermal conductivity (k, κ, or λ) is a measure of a material's ability to conduct heat. Heat transfer occurs at a lower rate in materials of low thermal conductivity than in materials of high thermal conductivity. Materials of high thermal conductivity are widely used in heat sink applications, while materials of low thermal conductivity are used as thermal insulation. Thermal conductivity can be defined in terms of the heat flow across a temperature difference.

In some examples, the cryogenic wire can have a thermal conductivity of 15 W/(m·K) or more at room temperature (e.g., 20 W/(m·K) or more, 25 W/(m·K) or more, 30 W/(m·K) or more, 35 W/(m·K) or more, 40 W/(m·K) or more, 45 W/(m·K) or more, 50 W/(m·K) or more, 60 W/(m·K) or more, 70 W/(m·K) or more, 80 W/(m·K) or more, 90 W/(m·K) or more, 100 W/(m·K) or more, 125 W/(m·K) or more, 150 W/(m·K) or more, 175 W/(m·K) or more, 200 W/(m·K) or more, or 225 W/(m·K) or more). In some examples, the cryogenic wire can have a thermal conductivity of 250 W/(m·K) or less at room temperature (e.g., 225 W/(m·K) or less, 200 W/(m·K) or less, 175 W/(m·K) or less, 150 W/(m·K) or less, 125 W/(m·K) or less, 100 W/(m·K) or less, 90 W/(m·K) or less, 80 W/(m·K) or less, 70 W/(m·K) or less, 60 W/(m·K) or less, 50 W/(m·K) or less, 45 W/(m·K) or less, 40 W/(m·K) or less, 35 W/(m·K) or less, 30 W/(m·K) or less, or 25 W/(m·K) or less). The thermal conductivity of the cryogenic wire at room temperature can range from any of the minimum values described above to any of the maximum values described above. For example, the cryogenic wire can have a thermal conductivity of from 15 to 250 W/(m·K) at room temperature (e.g., from 15 to 125 W/(m·K), from 125 to 250 W/(m·K), from 15 to 50 W/(m·K), from 50 to 100 W/(m·K), from 100 to 150 W/(m·K), from 150 to 200 W/(m·K), from 200 to 250 W/(m·K), from 15 to 225 W/(m·K), from 15 to 200 W/(m·K), from 15 to 175 W/(m·K), from 15 to 150 W/(m·K), from 20 to 250 W/(m·K), from 25 to 250 W/(m·K), from 50 to 250 W/(m·K), from 75 to 250 W/(m·K), from 100 to 250 W/(m·K), from 20 to 225 W/(m·K), from 25 to 200 W/(m·K), or from 50 to 150 W/(m·K)).

In some examples, the cryogenic wire can have a thermal conductivity of 25 W/(m·K) or more at 90 K (e.g., 30 W/(m·K) or more, 35 W/(m·K) or more, 40 W/(m·K) or more, 45 W/(m·K) or more, 50 W/(m·K) or more, 60 W/(m·K) or more, 70 W/(m·K) or more, 80 W/(m·K) or more, 90 W/(m·K) or more, 100 W/(m·K) or more, 125 W/(m·K) or more, 150 W/(m·K) or more, 175 W/(m·K) or more, 200 W/(m·K) or more, 250 W/(m·K) or more, 300 W/(m·K) or more, 350 W/(m·K) or more, 400 W/(m·K) or more, 450 W/(m·K) or more, 500 W/(m·K) or more, 600 W/(m·K) or more, 700 W/(m·K) or more, 800 W/(m·K) or more, 900 W/(m·K) or more, 1000 W/(m·K) or more, 1100 W/(m·K) or more, 1200 W/(m·K) or more, 1300 W/(m·K) or more, or 1400 W/(m·K) or more). In some examples, the cryogenic wire can have a thermal conductivity of 1500 W/(m·K) or less at 90 K (e.g., 1400 W/(m·K) or less, 1300 W/(m·K) or less, 1200 W/(m·K) or less, 1100 W/(m·K) or less, 1000 W/(m·K) or less, 900 W/(m·K) or less, 800 W/(m·K) or less, 700 W/(m·K) or less, 600 W/(m·K) or less, 500 W/(m·K) or less, 450 W/(m·K) or less, 400 W/(m·K) or less, 350 W/(m·K) or less, 300 W/(m·K) or less, 250 W/(m·K) or less, 225 W/(m·K) or less, 200 W/(m·K) or less, 175 W/(m·K) or less, 150 W/(m·K) or less, 125 W/(m·K) or less, 100 W/(m·K) or less, 90 W/(m·K) or less, 80 W/(m·K) or less, 70 W/(m·K) or less, 60 W/(m·K) or less, 50 W/(m·K) or less, 45 W/(m·K) or less, 40 W/(m·K) or less, 35 W/(m·K) or less, or 30 W/(m·K) or less). The thermal conductivity of the cryogenic wire at 90 K can range from any of the minimum values described above to any of the maximum values described above. For example, the cryogenic wire can have a thermal conductivity of from 25 to 1500 W/(m·K) at 90 K (e.g., from 25 to 750 W/(m·K), from 750 to 1500 W/(m·K), from 25 to 500 W/(m·K), from 500 to 1000 W/(m-K), from 1000 to 1500 W/(m·K), from 30 to 1500 W/(m·K), from 50 to 1500 W/(m·K), from 100 to 1500 W/(m·K), from 150 to 1500 W/(m·K), from 25 to 1400 W/(m·K), from 25 to 1300 W/(m·K), from 25 to 1200 W/(m·K), from 25 to 1100 W/(m·K), from 25 to 1000 W/(m·K), from 30 to 1400 W/(m·K), from 35 to 1200 W/(m·K), from 40 to 1100 W/(m·K), or from 50 to 1000 W/(m·K)).

In some examples, the cryogenic wire can have a thermal conductivity of 25 W/(m·K) or more at 70 K (e.g., 30 W/(m·K) or more, 35 W/(m·K) or more, 40 W/(m·K) or more, 45 W/(m·K) or more, 50 W/(m·K) or more, 60 W/(m·K) or more, 70 W/(m·K) or more, 80 W/(m·K) or more, 90 W/(m·K) or more, 100 W/(m·K) or more, 125 W/(m·K) or more, 150 W/(m·K) or more, 175 W/(m·K) or more, 200 W/(m·K) or more, 250 W/(m·K) or more, 300 W/(m·K) or more, 350 W/(m·K) or more, 400 W/(m·K) or more, 450 W/(m·K) or more, 500 W/(m·K) or more, 600 W/(m·K) or more, 700 W/(m·K) or more, 800 W/(m·K) or more, 900 W/(m·K) or more, 1000 W/(m·K) or more, 1250 W/(m·K) or more, 1500 W/(m·K) or more, 1750 W/(m·K) or more, 2000 W/(m·K) or more, or 2250 W/(m·K) or more). In some examples, the cryogenic wire can have a thermal conductivity of 2500 W/(m·K) or less at 70 K (e.g., 2250 W/(m·K) or less, 2000 W/(m·K) or less, 1750 W/(m·K) or less, 1500 W/(m·K) or less, 1250 W/(m·K) or less, 1000 W/(m·K) or less, 900 W/(m·K) or less, 800 W/(m·K) or less, 700 W/(m·K) or less, 600 W/(m·K) or less, 500 W/(m·K) or less, 450 W/(m·K) or less, 400 W/(m·K) or less, 350 W/(m·K) or less, 300 W/(m·K) or less, 250 W/(m·K) or less, 225 W/(m·K) or less, 200 W/(m·K) or less, 175 W/(m·K) or less, 150 W/(m·K) or less, 125 W/(m·K) or less, 100 W/(m·K) or less, 90 W/(m·K) or less, 80 W/(m·K) or less, 70 W/(m·K) or less, 60 W/(m·K) or less, 50 W/(m·K) or less, 45 W/(m·K) or less, 40 W/(m·K) or less, 35 W/(m·K) or less, or 30 W/(m·K) or less). The thermal conductivity of the cryogenic wire at 70 K can range from any of the minimum values described above to any of the maximum values described above. For example, the cryogenic wire can have a thermal conductivity of from 25 to 2500 W/(m·K) at 70 K (e.g., from 25 to 1250 W/(m·K), from 1250 to 2500 W/(m·K), from 25 to 500 W/(m·K), from 500 to 1000 W/(m·K), from 1000 to 1500 W/(m·K), from 1500 to 2000 W/(m·K), from 2000 to 2500 W/(m·K), from 30 to 2500 W/(m·K), from 40 to 2500 W/(m·K), from 50 to 2500 W/(m·K), from 100 to 2500 W/(m·K), from 150 to 2500 W/(m·K), from 250 to 2500 W/(m·K), from 25 to 2250 W/(m·K), from 25 to 2000 W/(m·K), from 25 to 1750 W/(m·K), from 25 to 1500 W/(m·K), from 30 to 2250 W/(m·K), from 35 to 2000 W/(m·K), from 40 to 1750 W/(m·K), or from 50 to 1500 W/(m·K)).

In some examples, the cryogenic wire can have a thermal conductivity of 25 W/(m·K) or more at 20 K (e.g., 30 W/(m·K) or more, 35 W/(m·K) or more, 40 W/(m·K) or more, 45 W/(m·K) or more, 50 W/(m·K) or more, 60 W/(m·K) or more, 70 W/(m·K) or more, 80 W/(m·K) or more, 90 W/(m·K) or more, 100 W/(m·K) or more, 125 W/(m·K) or more, 150 W/(m·K) or more, 175 W/(m·K) or more, 200 W/(m·K) or more, 250 W/(m·K) or more, 300 W/(m·K) or more, 350 W/(m·K) or more, 400 W/(m·K) or more, 450 W/(m·K) or more, 500 W/(m·K) or more, 600 W/(m·K) or more, 700 W/(m·K) or more, 800 W/(m·K) or more, 900 W/(m·K) or more, 1000 W/(m·K) or more, 1250 W/(m·K) or more, 1500 W/(m·K) or more, 1750 W/(m·K) or more, 2000 W/(m·K) or more, 2500 W/(m·K) or more, 3000 W/(m·K) or more, 3500 W/(m·K) or more, 4000 W/(m·K) or more, 4500 W/(m·K) or more, 5000 W/(m·K) or more, 6000 W/(m·K) or more, 7000 W/(m·K) or more, 8000 W/(m·K) or more, 9000 W/(m·K) or more, 10000 W/(m·K) or more, or 11000 W/(m·K) or more). In some examples, the cryogenic wire can have a thermal conductivity of 12,000 W/(m·K) or more at 20 K (e.g., 11000 W/(m·K) or less, 10000 W/(m·K) or less, 9000 W/(m·K) or less, 8000 W/(m·K) or less, 7000 W/(m·K) or less, 6000 W/(m·K) or less, 5000 W/(m·K) or less, 4500 W/(m·K) or less, 4000 W/(m·K) or less, 3500 W/(m·K) or less, 3000 W/(m·K) or less, 2500 W/(m·K) or less, 2000 W/(m·K) or less, 1750 W/(m·K) or less, 1500 W/(m·K) or less, 1250 W/(m·K) or less, 1000 W/(m·K) or less, 900 W/(m·K) or less, 800 W/(m·K) or less, 700 W/(m·K) or less, 600 W/(m·K) or less, 500 W/(m·K) or less, 450 W/(m·K) or less, 400 W/(m·K) or less, 350 W/(m·K) or less, 300 W/(m·K) or less, 250 W/(m·K) or less, 225 W/(m·K) or less, 200 W/(m·K) or less, 175 W/(m·K) or less, 150 W/(m·K) or less, 125 W/(m·K) or less, 100 W/(m·K) or less, 90 W/(m·K) or less, 80 W/(m·K) or less, 70 W/(m·K) or less, 60 W/(m·K) or less, 50 W/(m·K) or less, 45 W/(m·K) or less, 40 W/(m·K) or less, 35 W/(m·K) or less, or 30 W/(m·K) or less). The thermal conductivity of the cryogenic wire at 20 K can range from any of the minimum values described above to any of the maximum values described above. For example, the cryogenic wire can have a thermal conductivity of from 25 to 12,000 W/(m·K) at 20 K (e.g., from 25 to 6000 W/(m·K), from 6000 to 12000 W/(m·K), from 25 to 4000 W/(m·K), from 4000 to 8000 W/(m·K), from 8000 to 12000 W/(m·K), from 30 to 12000 W/(m·K), from 40 to 12000 W/(m·K), from 50 to 12000 W/(m·K), from 100 to 12000 W/(m·K), from 500 to 12000 W/(m·K), from 1000 to 12000 W/(m·K), from 25 to 11000 W/(m·K), from 25 to 10000 W/(m·K), from 25 to 9000 W/(m·K), from 25 to 8000 W/(m·K), from 25 to 7000 W/(m·K), from 25 to 6000 W/(m·K), from 25 to 5000 W/(m·K), from 30 to 11000 W/(m·K), from 50 to 10000 W/(m·K), from 100 to 9000 W/(m·K), or from 200 to 8000 W/(m·K)).

In some examples, the cryogenic wire can have an average diameter of 0.05 millimeters (mm) or more (e.g., 0.1 mm or more, 0.15 mm or more, 0.2 mm or more, 0.25 mm or more, 0.3 mm or more, 0.35 mm or more, 0.4 mm or more, 0.45 mm or more, 0.5 mm or more, 0.6 mm or more, 0.7 mm or more, 0.8 mm or more, 0.9 mm or more, 1 mm or more, 1.25 mm or more, 1.5 mm or more, 1.75 mm or more, 2 mm or more, 2.5 mm or more, 3 mm or more, 3.5 mm or more, 4 mm or more, 4.5 mm or more, 5 mm or more, 6 mm or more, 7 mm or more, 8 mm or more, 9 mm or more, or 10 mm or more). In some examples, the cryogenic wire can have an average diameter of 12 mm or less (e.g., 11 mm or less, 10 mm or less, 9 mm or less, 8 mm or less, 7 mm or less, 6 mm or less, 5 mm or less, 4.5 mm or less, 4 mm or less, 3.5 mm or less, 3 mm or less, 2.5 mm or less, 2 mm or less, 1.75 mm or less, 1.5 mm or less, 1.25 mm or less, 1 mm or less, 0.9 mm or less, 0.8 mm or less, 0.7 mm or less, 0.6 mm or less, 0.5 mm or less, 0.45 mm or less, 0.4 mm or less, 0.35 mm or less, 0.3 mm or less, 0.25 mm or less, 0.2 mm or less, 0.15 mm or less, or 0.1 mm or less). The average diameter of the cryogenic wire can range from any of the minimum values described above to any of the maximum values described above. For example, the cryogenic wire can have an average diameter of from 0.05 mm to 12.0 mm (e.g., from 0.05 mm to 6 mm, from 6 mm to 12 mm, from 0.04 mm to 4 mm, from 4 mm to 8 mm, from 8 mm to 12 mm, from 0.05 mm to 11 mm, from 0.05 mm to 10 mm, from 0.05 mm to 9 mm, from 0.05 mm to 8 mm, from 0.05 mm to 6 mm, from 0.05 mm to 5 mm, from 0.05 mm to 2.5 mm, from 0.05 mm to 1 mm, from 0.1 mm to 12 mm, from 0.25 mm to 12 mm, from 0.5 mm to 12 mm, from 1 mm to 12 mm, from 2 mm to 12 mm, from 5 mm to 12 mm, from 0.1 mm to 11 mm, from 0.25 mm to 10 mm, or from 0.5 mm to 5 mm).

In some examples, the conductors as used herein can chemically react with atmospheric air, and more specifically oxygen, such that the conductor tarnishes and is then no longer suitable as a conductor. Accordingly, in some examples, the first end of the cryogenic wire can be covered, thereby preventing the conductor from contacting atmospheric air at the first end. In some examples, the second end of the cryogenic wire can be covered, thereby preventing the conductor from contacting atmospheric air at the second end. Covering the end of a wire can include capping the wire end, crimping the wire end, or any other method preventing the conductor in the cryogenic wire from contacting the atmosphere (e.g., air and/or oxygen). Capping off a wire can include using a wire cap, also referred to as wire nut, to terminate the wire by covering the end with the cap so the conductor is not in contact with the atmosphere (e.g., air and/or oxygen). Crimping refers to compressing the end of a wire with a crimper to prevent the conductor from having any contact with the atmosphere.

In some examples, the cryogenic wire can further comprise a varnish, wherein the varnish is disposed on the cladding material, such that the cladding material is between the varnish and the conductor. For example, the varnish can coat an external surface of the cladding material and/or the cryogenic wire. Varnishes can be used to coat wires to achieve a number of different purposes, one of which is insulation. Insulating varnishes can coat the outer surface of wires and cure to form an electrical insulation film. Additives and solvents can be added to the varnish to facilitate certain applications. Varnishes, and more specifically insulating varnishes, can include enamel varnishes such as polyvinylformal enamels, polyurethane enamels, polyesterimide enamels, polyester enamels, polyamideimide enamels, polyimide enamels, and nylon enamels. In some examples, the varnish can be insulating. In some examples, the varnish can comprise enamel.

Also provided herein are multifilamentary cables comprising two or more of any of the cryogenic wires disclosed herein, wherein the two or more cryogenic wires are bound together. Wires in a multifilament cable can be bound, wherein binding wires can include methods such as, but not limited to, twisting, stranding, braiding, or coating the wires. Multifilamentary wires are often used as superconducting wires.

### Methods of Making

Also provided herein are methods of making any of the cryogenic wires disclosed herein. For example, also disclosed herein are methods of making a cryogenic wire, the method comprising at least partially filling a lumen of a conduit with the conductor, wherein the conduit includes a wall defining the lumen, wherein the wall comprises the cladding material, and wherein the conductor is a solid. As used herein, the conduit is a tube with a hollow central cavity, referred to as the lumen. The wall that forms the lumen of the conduit is made of the cladding material and conductor is disposed within the lumen of the conduit. The conductor can, for example, be a solid rod. In some examples, the conductor can be a powder (e.g., powder-in-tube). In some examples, the methods further comprise heating the cryogenic wire until the conductor it is molten. As used herein, molten means liquified, and in some embodiments, by heat. In some examples, the low mass density conductor can be in molten form. In some examples, the cryogenic wire has a cross-sectional area and a length, and the methods can further comprise drawing the cryogenic wire to decrease the cross-sectional area and increase the length of the cryogenic wire. In further examples, the cryogenic wire can be drawn through a series of dies, each having an incrementally smaller cross-sectional area, with a set of calendar rollers.

Also provided herein are methods of making a cryogenic wire, the cryogenic wire extending from a first end to a second end opposite and axially spaced apart from the first end, the methods comprising at least partially filling a lumen of a conduit with a conductor; wherein the conductor is molten, thereby being a molten conductor; wherein the conduit extends from a third end to a fourth end opposite and axially spaced apart from the third end; wherein the conduit comprises a wall defining the lumen, wherein the wall comprises a cladding material, wherein the cladding material comprises a ductile and malleable metal; thereby forming the cryogenic wire comprising the cladding material disposed around the conductor.

In some examples, at least partially filling the conduit with the conductor can comprise submerging the first end of the conduit in the molten conductor; and applying a negative pressure to the second end of the conduit to thereby pull the molten conductor into the lumen of the conduit. In some examples, the negative pressure can be applied by pulling a plunger on a syringe, wherein the syringe is in fluid communication with the lumen of the conduit. In some examples, the syringe is coupled to a second conduit, the second conduit is coupled to the second end of the (first) conduit, and the second conduit is in fluid communication with the syringe and the lumen of the conduit. In some examples, the second conduit can be a plastic heat-resistant hose.

In some examples, the negative pressure can be applied by a vacuum pump, the vacuum pump being in fluid communication with the lumen of the conduit. For example, the negative pressure inside the lumen of the conduit can be controlled by a needle valve, which can be located between the conduit and the vacuum pump.

As used herein, the application of negative pressure is used to pull molten conductor into the lumen of the conduit. There are various possible methods of applying negative pressure, one of which includes an assembly of a second conduit and a syringe in series with the conduit. An “in series” connection refers to an end to end connection wherein the connected objects are in continuation with each other. Pulling the plunger of the syringe applies negative pressure through the second conduit and the conduit, thus pulling the molten conductor into the conduit. The second conduit can include a conduit such as a plastic hose, wherein the plastic hose can be heat resistant.

In some examples, at least partially filling the conduit with the conductor occurs in an inert atmosphere. An inert atmosphere allows one to perform air-sensitive experiments and handle air-sensitive compounds. In some examples, an inert atmosphere can have an oxygen concentration 2% or less by volume (e.g., 1.75% or less, 1.5% or less, 1.25% or less, 1% or less, 0.75% or less, 0.5% or less, 0.25% or less, or 0.1% or less).

In some examples, the inert atmosphere can comprise helium, neon, argon, krypton, xenon, radon, or a combination thereof. In some examples, the inert atmosphere can comprise argon, nitrogen, or a combination thereof. In some examples, the inert atmosphere can comprise nitrogen. In some examples, the inert atmosphere can comprise argon. In some examples, the inert atmosphere can comprise entirely or close to entirely all nitrogen or entirely or close to entirely all argon. An inert atmosphere is often created in a glove box, which removes the atmospheric air and replaces it with inert gases, such as nitrogen or argon. The oxygen concentration discussed herein refers to the concentration of oxygen of the inert atmosphere in which the method disclosed herein is performed.

In some examples, the methods can further comprise heating a solid conductor until molten, thereby forming the molten conductor, wherein the solid conductor has a density of 5000 kg/m³ or less. In some examples, the heating can further anneal the cladding material. In some examples, the solid conductor can be a solid rod. In some examples, the solid conductor can be a powder. As used herein, powder refers to a substance that is in the form of fine dry particles or matrix. In some examples, the low mass density conductor can be in a solid powder. As used herein, a solid rod refers to a straight bar or cylinder made of a solid substance. In some examples, the low mass density conductor can be in a solid rod.

In some examples, heating the solid conductor until molten can comprise heating the solid conductor at temperature for an amount of time sufficient to melt the solid conductor. The temperature and the amount of time can be selected in view of the composition of the solid conductor and/or the amount of the solid conductor. In some examples, the cryogenic wire can be heated to a temperature 5 K or less above the melting point of the conductor. In certain examples, the cryogenic wire can be heated to a temperature 4 K or less, 3 K or less, 2 K or less, or 1 K or less above the melting point of the conductor. In further examples, the cryogenic wire can be heated to a temperature from 0 K to 5 K, 0 K to 4K, 0 K to 3 K, 0 K to 2 K, or 0 K to 1 K above the melting point of the conductor. In some examples, the cryogenic wire can be heated to a temperature from 1 K to 5 K, 2 K to 5 K, 3 K to 5 K, or 4 K to 5 K above the melting point of the conductor.

In some examples, the method further comprises cooling the molten conductor to solidify the molten conductor, such that the cryogenic wire comprises the cladding material disposed around a solid conductor. In some examples, the method further comprises cooling the cryogenic wire to room temperature before drawing the cryogenic wire. In some examples, the cryogenic wire can have a cross-sectional area and a length, and the methods can further comprise drawing the cryogenic wire to decrease the cross-sectional area and increasing the length of the cryogenic wire. In some examples, drawing the cryogenic wire can include drawing the cryogenic wire through a series of dies each having an incrementally smaller cross-sectional area.

Drawing is a process via which the cross-section of a wire is reduced and the length is concomitantly increased. A wire is drawn by pulling the wire through a single, or series, of drawing dies. Wires can be drawn individually or in bundles, wherein drawing in bundles is often used for very fine wires. Drawing wires in bundles involves separating the wires with a metal with similar properties but with a lower chemical resistance so that it can then be removed after drawing. The drawing dies used in drawing can be made of tool steel, tungsten carbide, or diamond. A wire can be prepared for drawing by tapering the end of the wire that is going to be pulled through the die first by hammering, filing, rolling, or swaging the end so that it fits through the die. Rolling the end of the wire can be achieved with a rolling mill. Once the end of the wire has been tapered such that it can fit into the die, the wire is pulled through the die. In some examples, the cryogenic wire can be drawn through the series of dies with a set of calendar rollers. A wire can require more than one draw through successively smaller dies to reach the desired size. In addition to a die, drawing can include use of a drawing bench, which includes a long table, a die stand containing the die, and a carriage used to grip and draw the wire.

In some examples, the method can further include submerging the cryogenic wire in mineral oil, silicon oil, or a combination thereof before drawing. In some examples, the method can further include submerging the cryogenic wire in mineral oil before drawing. Mineral oil encompasses any of various colorless, odorless, light mixtures of alkanes from a mineral source, which can be a distillate of petroleum. Mineral oil can be a liquid by-product of refining crude oil to make gasoline and other petroleum products. This type of mineral oil can be transparent, colorless oil that includes mainly alkanes and cycloalkanes. Mineral oil includes, but is not limited to, paraffinum liquidum, petrolatum, cera microcrystalline, microcrystalline wax, ozokerite, ceresine isoparaffin, paraffin, and synthetic wax.

In some examples, the methods can further include spooling the cryogenic wire. Spooling involves the winding of wire onto a cylinder or reel. In some embodiments, wire can be spooled for use in a particular machine or device. In further embodiments, spooling may be done to minimize the space that the wire takes up.

In some examples, the method can further include applying a varnish to coat the cryogenic wire. In some examples, the varnish can be insulating. In some examples, the varnish can comprise enamel.

In some examples, the methods can further include covering the first end of the cryogenic wire, thereby preventing the conductor from contacting atmospheric air at the first end. In some examples, covering the first end comprises capping the first end. In some examples, the methods can further include covering the second end of the cryogenic wire, thereby preventing the conductor from contacting atmospheric air at the second end. In some examples, covering the second end comprises capping the second end.

In some examples, the conductor can comprise lithium, beryllium, calcium, sodium, magnesium, titanium, or a combination thereof. In some examples, the conductor can comprise lithium or an alloy thereof, beryllium or an alloy thereof, calcium or an alloy thereof, sodium or an alloy thereof, magnesium or an alloy thereof, titanium or an alloy thereof, or a combination thereof.

In some examples, the cladding material can comprise copper, silver, or a combination thereof. In some examples, the cladding material can comprise copper. In some examples, the cladding material can comprise silver.

Also disclosed herein are methods of making a multifilamentary cable comprising two or more cryogenic wires, each of the two or more cryogenic wires independently comprising any of the cryogenic wires disclosed herein or made by any of the methods disclosed herein, the methods comprising binding the two or more cryogenic wires together, thereby forming the multifilamentary cable.

### Methods of Use

Also disclosed herein are methods of use of any of the cryogenic wires disclosed herein, any of the cryogenic wires made by any of the methods disclosed herein, and/or any of the multifilamentary cables disclosed herein.

For example, the cryogenic wires can be used in areas such as electric power transmission or electric power distribution. Further, the cryogenic wires can be used for inductors or transformer windings in cryogenic power electronics. Other applications of the cryogenic wires include cryogenic microwave cables, cryogenic radio frequency (RF) cables, cryogenic multi-channel ribbon cable, quantum computers, and quantum internet applications. In some examples, the cryogenic wires can be used in power cables.

A number of embodiments of the disclosure have been described. Nevertheless, it will be understood that various modifications may be made without departing from the spirit and scope of the invention. Accordingly, other embodiments are within the scope of the following claims. By way of non-limiting illustration, examples of certain embodiments of the present disclosure are given below.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention, which are apparent to one skilled in the art.

Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric. There are numerous variations and combinations of reaction conditions, e.g., component concentrations, temperatures, pressures, and other reaction ranges and conditions that can be used to optimize the product purity and yield obtained from the described process. Only reasonable and routine experimentation will be required to optimize such process conditions.

### Example 1

Cryogenic wires have a higher thermal conductivity and higher electrical conductivity, than other conventional conductors (such as copper wires). Because of this, cryogenic wires can be used at cryogenic temperatures without a decrease in their electrical performance. Cryogenic wires allow for extremely high current with minimal electrical losses (e.g., at cryogenic temperatures).

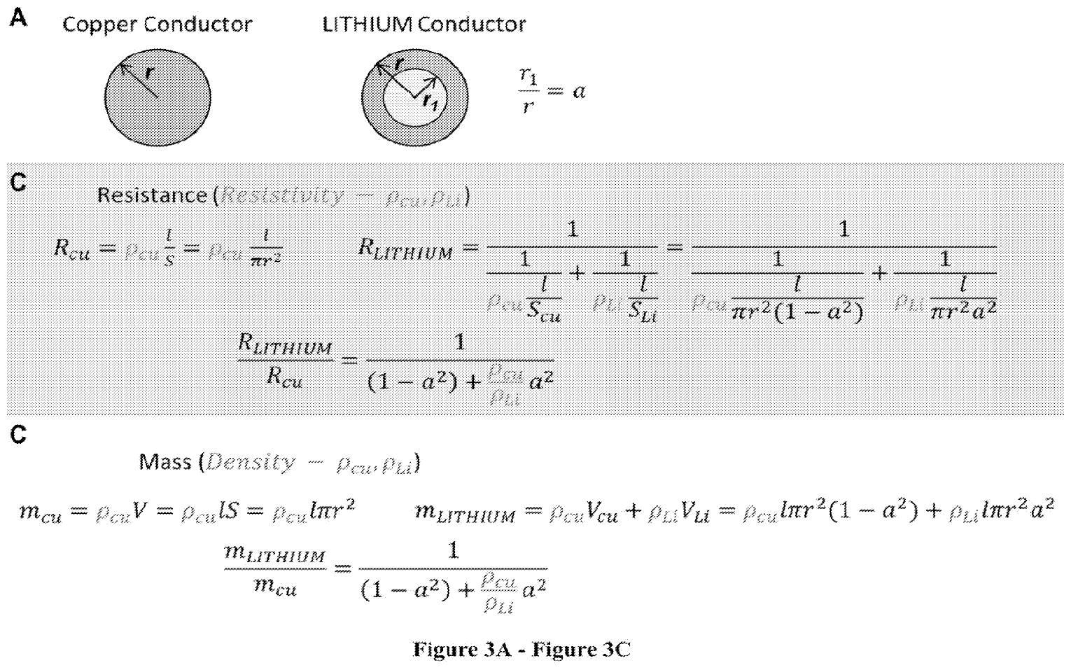

The residual resistivity ratio (RRR) is defined by the following equation:

$$RRR = {R}_{RT} / {R}_{4 K} = {ρ}_{295 K} / {ρ}_{4 K}$$

wherein resistance is calculated in accordance with the equation in FIG. 3B.

Conductivity per unity density is defined by the following equation:

$$Conductivity per unit density = \frac{1}{( resistivity \times density )}$$

wherein mass and density are calculated in accordance with the equation in FIG. 3C.

The physical properties of certain low mass density metals are summarized in Table 1. The conductivity per unit density of certain low mass density metals is summarized in Table 2.

TABLE 1
Physical properties of low mass density metals.

| | | Electrical | Electrical | Electrical | Electrical | Thermal |
|---|---|---|---|---|---|---|
| | Density | resistivity | resistivity | resistivity | resistivity | conductivity |
| | at RT | at RT | at 100 K | at 77 K | at 20 K | at RT |
| | [kg/m³] | [Ωm] | [Ωm] | [Ωm] | [Ωm] | [W/m/K] |
| Cu | 8960 | 1.68E−08 | 3.40E−09 | 1.90E−09 | 1.00E−11 | 401 |
| Al | 2700 | 2.65E−08 | 4.40E−09 | 2.20E−09 | 7.00E−12 | 237 |
| Li | 534 | 9.28E−08 | 1.73E−08 | 1.00E−08 | 1.22E−10 | 84.7 |
| Na | 968 | 4.81E−08 | 1.16E−08 | 7.96E−09 | 1.56E−10 | 141 |
| K | 862 | 7.28E−08 | 1.79E−08 | 1.34E−08 | 1.17E−09 | 102.4 |
| Be | 1850 | 3.62E−08 | 1.33E−09 | 7.50E−10 | 3.36E−10 | 200 |
| Mg | 1738 | 4.43E−08 | 9.10E−09 | 5.57E−09 | 1.23E−10 | 156 |
| Ca | 1550 | 3.36E−08 | 9.10E−09 | 6.50E−09 | 6.00E−10 | 98 |
| Ti | 4506 | 4.31E−07 | 7.90E−08 | 4.45E−08 | 2.00E−10 | 21.9 |

| | Thermal | Thermal | Thermal |
|---|---|---|---|
| | conductivity | conductivity | conductivity |
| | at 90 K | at 70 K | at 20 K |
| | [W/(m · K)] | [W/m/K] | [W/m/K] |
| Cu | 508 | 647 | 10800 |
| Al | 342 | 585 | 11700 |
| Li | | | |
| Na | | | |
| K | | | |
| Be | 1296 | 2243 | 3611 |
| Mg | 178 | 249 | 2720 |
| Ca | | | |
| Ti | 31.5 | 34 | 27.5 |

TABLE 2
Electrical conductivity per unit density of low mass density metals.

| | RT | 100 K | 77 K | 20 K |
|---|---|---|---|---|
| Cu | 6.64E+03 | 3.28E+04 | 5.87E+04 | 1.12E+07 |
| Al | 1.40E+04 | 8.42E+04 | 1.68E+05 | 5.29E+07 |
| Li | 2.02E+04 | 1.08E+05 | 1.87E+05 | 1.53E+07 |
| Na | 2.15E+04 | 8.92E+04 | 1.30E+05 | 6.62E+06 |
| K | 1.59E+04 | 6.48E+04 | 8.66E+04 | 9.92E+05 |
| Be | 1.49E+04 | 4.06E+05 | 7.21E+05 | 1.61E+06 |
| Mg | 1.30E+04 | 6.32E+04 | 1.03E+05 | 4.68E+06 |
| Ca | 1.92E+04 | 7.09E+04 | 9.93E+04 | 1.08E+06 |
| Ti | 5.15E+02 | 2.81E+03 | 4.99E+03 | 1.11E+06 |

### Example 2

This example describes the manufacturing of copper-clad lithium wires in an Argon gas environment. Molten lithium was casted (vacuum-assisted) into a thin-walled copper rod. The copper-clad lithium rod was crimped and drawn through dies to reach the desired cable dimensions.

Storage Requirements. The lithium was stored in mineral oil or under an inert atmosphere, such as Argon. Lithium (density=0.534 g/cm³) will float in mineral oil (density=0.8 g/cm³). The pieces of lithium stored in oil were thoroughly coated. Storage in an inert atmosphere glove box was an appropriate option.

Materials. Materials included lithium (sealed in an inert environment), heating tape and controller, syringe, transparent heat resistant plastic hose, mineral oil, crimpers, plyers, metal can, isopropanol, copper rod, crucible, test tube holder, humidity sensor, oxygen sensor, hot plate, and extinguishing powder.

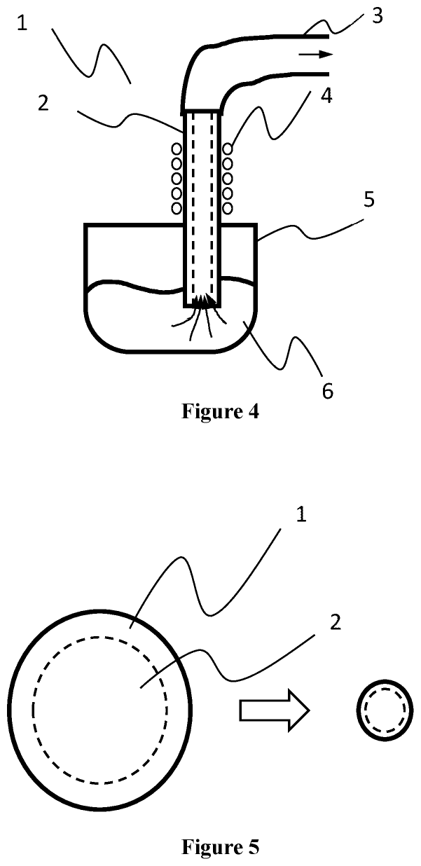

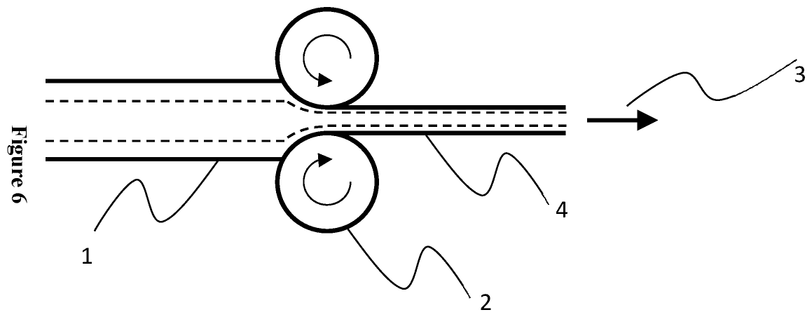

Operating Procedure. The copper rod, plastic hose, and syringe connections were pre-assembled and heating tape was wrapped around the copper rod. (See FIG. 4.) This assembly was mounted onto the test tube holder. All were assembled in the glove box. The exhaust port of the glove box was opened, and it was purged with Argon, such that the Argon displaced air from inside the glove box. The oxygen measured less than 2%. Lithium samples that were stored in mineral oil were cleaned. Upon cleaning, the lithium was transferred into the stainless-steel crucible and the crucible was placed on top of the hot plate.

The hot plate and heating tape were set to 185° C. and turned on. Once the lithium melted, the copper rod assembly was lowered into the molten lithium. One of the ends of the copper rod was submerged in the molten lithium. A vacuum to draw lithium through the copper pipe was created by pulling the syringe plunger. Once the pipe was full, the copper rod assembly was removed from the molten lithium. The crucible and copper rod were then allowed to cool, and the lithium solidified. Once cooled, the copper clad lithium was removed from the assembly, and both ends of the wire were crimped. The solidified lithium was transferred into a mineral oil container and the container was closed.

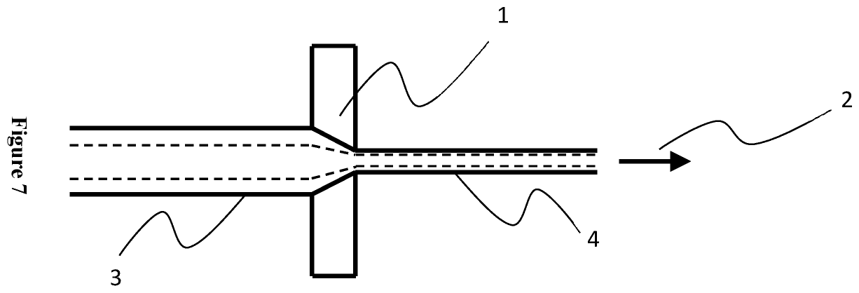

A rolling mill was used to create a tapered profile on one of the copper-clad lithium rod ends. (See FIG. 6.) The starting drawing hole on the die was identified by using the untampered end of the copper-clad lithium rod. Using the drawing bench and die, the rod was drawn to the desired dimension by pulling the rod's tapered end first through the progressively smaller holes.

### Example 3

An exemplary method and product are disclosed herein using certain metals of low mass density (e.g., Lithium, Beryllium, Calcium, Sodium, Potassium, Magnesium, Titanium) as conductors for cryogenic power cables. The example use and apparatus exploits the improved electrical performance of said conductors at low temperatures. As the material is cooled down, high conductivity per unit density values can be achieved, making them attractive for applications with high gravimetric power density needs. Some of the preceding Examples show the conductivity per unit density for different materials as a function of temperature.

The most promising conductor materials, however, do not have the necessary mechanical properties, such as ductility, to allow them to be drawn into wires directly. Therefore, the conductor material is cladded with copper, silver, or another highly ductile and malleable metal, which allows the wire to be drawn using standard wire drawing techniques, tools, and facilities. Furthermore, the suggested conductor metals are chemically highly reactive, which would complicate the manufacturing process and limit the type of applications. The cladding by copper or silver reduces these problems significantly and allows the use of standard joining techniques such as soldering and crimping, which would otherwise be much more problematic. The exemplary cryogenic conductor wire may be used an interconnection between two or more devices, allowing communication, power transfer, and energy storage (e.g., inductor winding).

The material properties of Lithium, Beryllium, Calcium, Sodium, Potassium, Magnesium, and Titanium, and various associated alloys illustrate their suitability for cryogenic conductors. The exemplary embodiments may operate in cryogenic temperatures.

The process can begin with filling a copper or silver pipe with one of the above-mentioned low density metals. The filler metal can be introduced either in molten form, as a solid powder, or as a solid rod. Both ends can be capped off to avoid chemical reaction with atmospheric air. This solid rod is then pulled through a series of increasingly smaller dies, each reducing the diameter and increasing the length of the wire. The wire can be spooled up to reduce the amount of space needed. Depending on the application, a type of insulating enamel varnish can be applied, and multiple wires can be combined to a stranded (multi-filamentary) cable.

The wires can be used in various applications, such as for electric power transmission and electric power distribution where high gravimetric power density is needed. The use of these wires makes sense especially in applications where a cryogenic cooling medium is already available. This includes future electric aircraft, which make use of cryogenic fuels such as liquid hydrogen, liquid methane, or liquid natural gas. The global aerospace services market is worth over nine trillion U.S. dollars, with key markets in the United States, France, China, and UK. Two of the largest aerospace and defense manufacturers in the world are Boeing and Airbus with revenue streams of about 76.6 billion U.S. dollars and 78.9 billion euros, respectively.

Furthermore, these conductors can be used for inductors and transformer windings in cryogenic power electronics, where they provide the same advantage of increased gravimetric power density.

Copper-clad aluminum conductors are in use for electrical power applications where the gravimetric power density matters. The process of cladding the aluminum conductor and drawing it into wires is well-established. These conductors are typically used at room temperature. However, at cryogenic temperature, metals like calcium and lithium provide a significantly higher mass-specific conductivity. Copper-clad steel wires are used for welding applications. The copper cladding helps to avoid oxidation (rusting) of the carbon steel wire and helps to reduce the friction in automatic welding apparatus. Superconducting wires, such as NbTi, Nb₃Ti, MgB₂, or Bi₂Sr₂Caₙ₋₁CuₙO₂ₙ₊₄₊ₓ, use again a similar process. In this case, the silver cladding serves additional chemical and structural purposes.

Above, the term exotic is used to label a subset of conducting materials that are not commonly used as room temperature conductors. Furthermore, the conductors used herein can be high purity metals, as resistivity, at low temperatures, can be directly correlated to the purity of the material.

Commercially available cryogenic wires include Beryllium, Phosphor bronze, manganin, nichrome, calcium, among others, are readily used to form alloys with more common conductors and are commercially available as wires. Most, if not all, of these alloyed solutions are driven by improved mechanical properties, and although some are marketed for cryogenic temperatures, none are lightweight. While certain lightweight conductors have been described by Yamaguchi and Kovác, they cannot cater to superconductivity as the operating temperatures described in Yamaguchi and Kovác, 77K (Liquid Nitrogen) and 33K (Liquid Hydrogen), will limit the enhanced features (Yamaguchi et al, Superconductor Science and Technology, 2020, 34(1). 014001; Kovác et al. Scientific reports, 2018, 8(1), 1-7).

Other advantages which are obvious, and which are inherent to the invention, will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods and compositions of the appended claims are not limited in scope by the specific methods and compositions described herein, which are intended as illustrations of a few aspects of the claims and any methods and compositions that are functionally equivalent are intended to fall within the scope of the claims. Various modifications of the methods and compositions in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A cryogenic wire extending from a first end to a second end opposite and axially spaced apart from the first end, the cryogenic wire comprising:
a conductor having a mass density of 5000 kg/m³ or less; and
a cladding material disposed around the conductor, the cladding material comprising a ductile and malleable metal.

2. (canceled)

3. The cryogenic wire of claim 1, wherein the conductor comprises lithium or an alloy thereof, beryllium or an alloy thereof, calcium or an alloy thereof, sodium or an alloy thereof, magnesium or an alloy thereof, titanium or an alloy thereof, or a combination thereof.

4. The cryogenic wire of claim 1, wherein the cladding material comprises aluminum, copper, silver, or a combination thereof.

5. (canceled)

6. (canceled)

7. The cryogenic wire of claim 1, wherein the conductor has an electrical conductivity per unit density of from 500 to 22,000 S·m²/kg, an electrical resistivity of from 1.6×10⁻⁷ to 4.5×10⁻⁷ Ω·m, a thermal conductivity of from 15 to 250 W/(m·K), or any combination thereof at room temperature.

8. The cryogenic wire of claim 1, wherein the conductor has an electrical conductivity per unit density of from 2,500 to 410,000 S·m²/kg, an electrical resistivity of from 1.0×10⁻⁹ to 8.0×10⁻⁷ Ω·m or any combination thereof at 100 K.

9. The cryogenic wire of claim 1, wherein the conductor has an electrical conductivity per unit density of from 4,500 to 750,000 S·m²/kg, an electrical resistivity of from 7.3×10⁻¹⁰ to 4.7×10⁻⁷ Ω·m, or any combination thereof at 77 K.

10. The cryogenic wire of claim 1, wherein the conductor has an electrical conductivity per unit density of from 950,000 to 16,000,000 S·m²/kg, an electrical resistivity from 1.0×10⁻¹² to 1.5×10⁻⁹ Ω·m, a thermal conductivity of from 25 to 12,000 W/(m·K), or any combination thereof at 20 K.

11.-15. (canceled)

16. The cryogenic wire of claim 1, wherein the cryogenic wire has a thermal conductivity of from 25 to 1500 W/(m·K) at 90 K.

17. The cryogenic wire of claim 1, wherein the cryogenic wire has a thermal conductivity of from 25 to 2500 W/(m·K) at 70 K.

18. (canceled)

19. The cryogenic wire of claim 1, wherein the cryogenic wire has an average diameter of from 0.05 millimeters (mm) to 12.0 mm.

20. The cryogenic wire of claim 1, wherein the first end of the cryogenic wire is covered, thereby preventing the conductor from contacting atmospheric air at the first end.

21. The cryogenic wire of claim 20, wherein the first end, the second end, or any combination thereof is capped.

22. The cryogenic wire of claim 1, wherein the second end of the cryogenic wire is covered, thereby preventing the conductor from contacting atmospheric air at the second end.

23. (canceled)

24. The cryogenic wire of claim 1, further comprising a varnish, wherein the varnish is disposed on the cladding material, such that the cladding material is between the varnish and the conductor.

25. The cryogenic wire of claim 24, wherein the varnish is insulating.

26. The cryogenic wire of claim 24, wherein the varnish comprises enamel.

27. A multifilamentary cable comprising two or more cryogenic wires, each of the two or more cryogenic wires independently being the cryogenic wire of claim 1, wherein the two or more cryogenic wires are bound together.

28. A method of making the cryogenic wire of claim 1, the method comprising:
at least partially filling a lumen of a conduit with the conductor,
wherein the conduit comprises a wall defining the lumen,
wherein the wall comprises the cladding material, and
wherein the conductor is a solid.

29.-35. (canceled)

36. A method of making a cryogenic wire, the cryogenic wire extending from a first end to a second end opposite and axially spaced apart from the first end, the method comprising:
at least partially filling a lumen of a conduit with a conductor,
wherein the conductor is molten, thereby being a molten conductor,
wherein the conduit extends from a third end to a fourth end opposite and axially spaced apart from the third end,
wherein the conduit comprises a wall defining the lumen,
wherein the wall comprises a cladding material,
wherein the cladding material comprises a ductile and malleable metal,
thereby forming the cryogenic wire comprising the cladding material disposed around the conductor.

37.-67. (canceled)

68. A method of making a multifilamentary cable comprising two or more cryogenic wires, each of the two or more cryogenic wires independently being made by the method of claim 28, the method comprising binding the two or more cryogenic wires together.
